(19) United States
(12) Patent Application Publication
(10) Pub. No.: US 2025/0351648 A1
(43) Pub. Date: Nov. 13, 2025

(54) SYTEMS AND METHODS FOR DEPOSITING PHOSPHOR CONTAINING INK

(71) Applicant: EDISON INNOVATIONS LLC, ALLEN, TX (US)

(72) Inventors: Aharon Yakimov, Niskayuna, NY (US); Gurvinder Singh Khinda, Niskayuna, NY (US); James E. Murphy, Niskayuna, NY (US); Felippe Pavinatto, Niskayuna, NY (US); Daniel DePuccio, Niskayuna, NY (US); Kathleen Maleski, Niskayuna, NY (US); Jerry Liu, Niskayuna, NY (US); Zeying Chen, Niskayuna, NY (US)

(21) Appl. No.: 18/862,598

(22) PCT Filed: May 4, 2023
(86) PCT No.: PCT/US2023/020927

§ 371 Date: Nov. 4, 2024

Related U.S. Application Data
(60) Provisional application No. 63/338,428, filed on May 4, 2022.
(60) Provisional application No. 63/338,868, filed on May 5, 2022.
(60) Provisional application No. 63/453,396, filed on Mar. 20, 2023.
(60) Provisional application No. 63/498,414, filed on Apr. 26, 2023.

(51) Int. Cl. H10H 29/851; C09D 11/037; C09D 11/50

(52) U.S. Cl. CPC H10H 29/8512; C09D 11/037; C09D 11/50

(57) ABSTRACT

Phosphor ink compositions and systems and methods for depositing such phosphor containing ink are disclosed. An ink composition of in accordance with the present disclosure comprises a phosphor material comprising a Mn⁴⁺ doped phosphor of Formula 1 Aₓ[MF_{y}]:Mn⁴⁺ (I) and at least one binder material or solvent, wherein the Mn⁴⁺ doped phosphor has a D50 particle size from about 0.5 microns to about 15 microns, and wherein the ink composition has a viscosity from more than 2,000 cP to about 30,000 cP, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

### CROSS REFERENCE TO RELATED APPLICATIONS

This application claims priority to U.S. Provisional Patent Application Ser. No. 63/338,428 filed May 4, 2022 for “PHOSPHORS, INK FORMULATIONS AND FILMS”, U.S. Provisional Patent Application Ser. No. 63/338,868 filed May 5, 2022 for “PRINTING, FILMS AND SUBSTRATES”, U.S. Provisional Patent Application Ser. No. 63/453,396 filed Mar. 20, 2023 for “PHOSPHOR CONVERTED MICROLED ARRAY WITH REFLECTIVE LAYER FOR A TRANSPARENT DISPLAY ARCHITECTURE”, and U.S. Provisional Patent Application Ser. No. 63/498,414 filed Apr. 26, 2023 for “PHOSPHOR INK PRINTED COLOR FILTER PARTS”, which are hereby incorporated by reference in their entirety.

### BACKGROUND

The subject matter described herein relates generally to depositing ink containing phosphor materials for lighting and display applications.

Narrow band emission phosphor materials achieve high color quality in lighting and displays based on LEDs. Next generation displays may incorporate mini-LEDs and micro-LEDs having active areas of 10,000 μm² or less that are capable of generating light visible to the human eye at very low drive currents. Mini-LEDs are LEDs with a size of about 100 μm to 0.7 mm. For micro-LEDs, the displays may be self-emissive or include miniaturized backlighting and arrayed with individual LEDs smaller than 100 μm.

New methods of applying phosphor materials onto the miniaturized μm-sized LED elements need to be developed to enable the full potential of mini-LED and micro-LED technologies. Coating and printing films, such as ink jet printing, spin coating or slot die coating of phosphor materials is being developed to prepare LEDs including small size LEDs.

Ink jet printable ink has been prepared using quantum dots. Quantum dot material has nanometer particle sizes with a strong absorption coefficient. Quantum dots suffer from low quantum efficiency (QE) and poor thermal stability, which significantly limit their practical applications.

Phosphors have improved properties over quantum dot materials. Phosphors for use with small size LEDs must have a correspondingly small size. Printing and coating compositions require stable dispersions and phosphor materials with common organic solvents can create sedimentation or phase separation which is undesirable for subsequent coating and printing processes. Also, phosphor materials with small particle sizes tend to agglomerate when mixed with commonly used solvents making it unsuitable for ink compositions or formulations.

### BRIEF DESCRIPTION

In one embodiment, an ink composition is provided. The ink composition includes a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from more than 2000 cP to about 30,000 cP

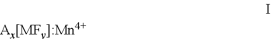

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a method for inkjet printing, flexographic printing, or microdispensing printing is disclosed. The method includes printing an ink composition, wherein the ink composition includes a low viscosity ink composition including a phosphor material including a Mn⁴⁺ doped phosphor of formula 1 and at least one binder material or solvent, wherein the Mn⁴⁺ doped phosphor has a D50 particle size from about 0.5 microns to about 5 microns, and wherein the ink composition has a viscosity from about 10 cP to about 1000 cP

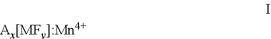

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a method for screen printing, direct write printing, aerosol jet printing, gravure printing, or flexographic printing, or microdispensing printing, The method includes printing an ink composition, wherein the ink composition includes a medium viscosity ink composition including a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from about 1000 cP to about 10,000 cP

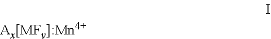

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a method for direct write printing or extruding is disclosed. The method comprises includes printing or extruding an ink composition, wherein the ink composition includes a high viscosity phosphor doped ink composition including a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from about 10,000 cP to about 30,000 cP

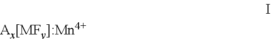

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a device comprising an LED light source optically coupled and/or radiationally connected to a phosphor composition comprising a phosphor material comprising a Mn⁴⁺ doped phosphor of formula 1, wherein the Mn⁴⁺ doped phosphor has a D50 particle size from about 0.5 microns to about 15 microns, and wherein the phosphor composition coupled to the LED light source has an aspect ratio of at least 0.1,

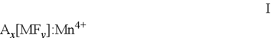

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a color filter part is disclosed. The color filter part comprises a well, a first ink phosphor composition and a second ink phosphor composition, the first ink composition comprising a high refractive index and the second ink phosphor composition comprising a low refractive index, wherein the second ink phosphor composition is located proximate to a surface through which excitation light enters, the first ink phosphor composition and the second ink phosphor composition including a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from about 10,000 cP to about 30,000 cP

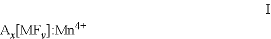

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a method comprising depositing a first ink composition into a well of a color filter part, and subsequently, depositing a second ink composition into the well of the color filter part, wherein the first ink composition has a high refractive index and the second ink composition has a low refractive index, wherein the second ink composition is located proximate to a surface through which excitation light enters, wherein the first ink phosphor composition and the second ink phosphor composition include a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from about 10,000 cP to about 30,000 cP

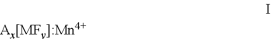

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a light emitting array is disclosed. The light emitting array comprises a plurality of micro-LEDs, each micro-LED enclosed in a banked structure or a well structure, the banked structure or well structure configured to contain an ink composition deposited within the bank structure or the well structure, the phosphor ink composition including a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from about 10,000 cP to about 30,000 cP

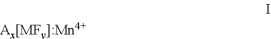

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, a transparent display is disclosed. The transparent display comprises a micro-LED array coated with a phosphor composition, wherein the transparent display has a transparency of at least 50%, the phosphor ink composition comprising a Mn⁴⁺ doped phosphor of formula 1, wherein the Mn⁴⁺ doped phosphor has a D50 particle size from about 0.5 microns to about 15 microns, and wherein the phosphor composition has an aspect ratio of at least 0.1,

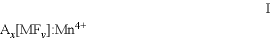

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

### DRAWINGS

These and other features, aspects, and advantages of the present disclosure will become better understood when the following detailed description is read with reference to the accompanying drawings in which like characters represent like parts throughout the drawings, wherein:

FIG. 1A is a schematic cross-sectional view of a device, in accordance with one embodiment of the disclosure.

FIG. 1B is a schematic cross-sectional view of a device in accordance with an exemplary embodiment.

FIG. 1C is a schematic cross-sectional view of a device in accordance with an exemplary embodiment.

FIG. 1D is a schematic cross-sectional view of a device in accordance with an exemplary embodiment.

FIG. 1E is a schematic cross-sectional view of a device in accordance with an exemplary embodiment.

FIG. 2 is a schematic cross-sectional view of a lighting apparatus, in accordance with one embodiment of the disclosure.

FIG. 3 is a schematic cross-sectional view of a lighting apparatus, in accordance with another embodiment of the disclosure.

FIG. 4 is a cutaway side perspective view of a lighting apparatus, in accordance with one embodiment of the disclosure.

FIG. 5A is a schematic perspective view of a surface-mounted device (SMD), in accordance with one embodiment of the disclosure.

FIG. 5B is a schematic cross-sectional view of an SMD in accordance with an exemplary embodiment.

FIG. 5C is a schematic cross-sectional view of a device in accordance with an exemplary embodiment.

FIG. 6 is a schematic diagram of a contact stencil printing system, in accordance with an embodiment of the disclosure.

FIG. 7 is a schematic diagram of a snap-off stencil printing system, in accordance with an embodiment of the disclosure.

FIGS. 8A-8D are schematic diagrams of a printing well arrangement, in accordance with an embodiment of the disclosure.

FIG. 9 is a schematic diagram of a bank arrangement, in accordance with an embodiment of the disclosure.

FIG. 10 is a diagram of a composition deposited on a substrate using the contact stencil printing system of FIG. 6.

FIG. 11 is a diagram of a composition deposited on a substrate using the snap-off stencil printing system of FIG. 7.

FIGS. 12A and 12B comprise graphs representing the aspect ratio of a printed ink composition pattern deposited using snap-off stencil printing, in accordance with an embodiment of the disclosure.

FIGS. 13A and 13B illustrate printed ink composition pattern deposited via snap-off stencil printing and FIG. 13B is a photoluminescence intensity map of the pattern.

FIGS. 14A and 14B are schematic diagrams of a high precision pick and place system, in accordance with an embodiment of the present disclosure.

FIG. 15 is a dip coating system, in accordance with an embodiment of the present disclosure.

FIGS. 16A and 16B are a top view and a side view, respectively, of an example red-green-blue (RGB) pixel, in accordance with an embodiment of the present disclosure.

FIG. 17 is a graph comparing red light emission by color filter parts with KSF phosphor filled red subpixel comprising a depth of 8 μm versus a depth of 16 μm, in accordance with an embodiment of the present disclosure.

FIG. 18 illustrates a photoluminescence mapping of a blank substrate.

FIG. 19 illustrates a photoluminescence mapping of a KSF filled red subpixel.

FIG. 20 illustrates a graph illustrating percent external quantum efficiency (EQE).

FIG. 21 is a schematic diagram of hybrid conductive grid, in accordance with an embodiment of the present disclosure.

FIG. 22 is a contour plot of the color point of an example LED array.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur, or the material is not present.

Square brackets in the formulas indicate that at least one of the elements is present in the phosphor material, and any combination of two or more thereof may be present. For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺·Mn²⁺; Sr₃MgSi₂O₈:Eu²⁺·Mn²; or Ba₃MgSi₂O₈:Eu²⁺·Mn²⁺. Formula with an activator after a colon “:” indicates that the phosphor material is doped with the activator. Formula showing more than one activator separated by a “,” after a colon “:” indicates that the phosphor material is doped with either activator or both activators. For example, the formula [Ca,Sr,Ba]₃MgSi₂O₈:Eu²⁺,Mn²⁺ encompasses [Ca,Sr,Ba]₃MgSi₂O₈:Eu²⁺, [Ca,Sr,Ba]₃MgSi₂O₈:Mn²⁺ or [Ca,Sr,Ba]₃MgSi₂O₈:Eu²⁺ and Mn²⁺.

In one aspect, an ink composition is provided. The ink composition includes a phosphor material including a Mn⁴⁺ doped phosphor of formula 1 and at least one binder material or solvent, wherein the Mn⁴⁺ doped phosphor has a D50 particle size from about 0.5 microns to about 15 microns, and wherein the ink composition has a viscosity from more than 2000 cP to about 30,000 cP

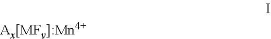

where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The ink composition may be tailored to a specific printing application. For example, the ink composition may be tailored to any one of the following printing applications: inkjet printing, flexographic printing, or microdispensing printing, screen printing, direct write printing, aerosol jet printing, gravure printing, and the link. Additionally, or alternatively, the ink composition may be tailored for extrusion. For example, low viscosity ink compositions may be tailored for inkjet printing, flexographic printing, and/or microdispensing printing; medium viscosity inks may be tailored for screen printing, direct write printing, aerosol jet printing, gravure printing, flexographic printing, and/or microdispensing printing; and high viscosity inks may be tailored for high viscosity screen printing, direct write printing, and/or extruding.

The ink composition includes phosphor material. The type, quantity, and size of phosphor is determined by the optical application specifically the color point and optical density.

The phosphor material may be present in the ink composition from about 5 wt % to about 70 wt %. In another embodiment, the phosphor material is present from about 30 wt % to about 60 wt %. In another embodiment, the phosphor material is present from about 10 wt % to about 50 wt %. The wt % for the phosphor material is based on the total weight of the ink composition.

The Mn⁴⁺ doped phosphors of formula I are complex fluoride materials, or coordination compounds, containing at least one coordination center surrounded by fluoride ions acting as ligands, and charge-compensated by counter ions as necessary. For example, in K₂SiF₆:Mn⁴⁺ the coordination center is Si and the counterion is K. The activator ion (Mn⁴⁺) also acts as a coordination center, substituting part of the centers of the host lattice, for example, Si. The host lattice (including the counter ions) may further modify the excitation and emission properties of the activator ion.

In particular embodiments, the coordination center of the phosphor, that is, M in formula I, is Si, Ge, Sn, Ti, Zr, Al, Ga, In, Sc, Y, La, Nb, Ta, Bi, Gd, or a combination thereof. More particularly, the coordination center may be Si, Ge, Ti, or a combination thereof. The counterion, or A in formula I, may be Li, Na, K, Rb, Cs, or a combination thereof, more particularly K or Na. Examples of phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, K₂[GeF₆]Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆]K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴¹. In particular embodiments, the phosphor of formula I is K₂SiF₆:Mn⁴⁺ (PFS) or Na₂[SiF₆]:Mn⁴⁺ (NSF).

The amount of activator Mn incorporation in the Mn⁴⁺ doped phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue LED.

In one embodiment, the red-emitting Mn⁴⁺ doped phosphor has a Mn loading or Mn % of at least 1 wt %. In another embodiment, the red-emitting phosphor has a Mn loading of at least 1.5 wt %. In another embodiment, the red-emitting phosphor has a Mn loading of at least 2 wt %. In another embodiment, the red-emitting phosphor has a Mn % of at least 3 wt %. In another embodiment the Mn % is greater than 3.0 wt %. In another embodiment, the content of Mn in the red-emitting phosphor is from about 1 wt % to about 4 wt %. In another embodiment, the red-emitting phosphor mas a Mn % from about 2 wt % to about 5 wt %.

In one embodiment, the Mn⁴⁺ doped phosphor may be a manganese-doped potassium fluorosilicate, such as K₂SiF₆:Mn⁴⁺ (PFS). PFS has a narrow band emission having multiple peaks with an average full width at half maximum (FWHM) of less than 4 nm. In another embodiment, the red-emitting phosphor may be Na₂SiF₆:Mn⁴⁺ (NFS).

In one embodiment, Mn⁴⁺ doped phosphors may be further treated, such as by annealing, wash treatment, roasting or any combination of these treatments. Post-treatment processes for Mn⁴⁺ doped phosphors are described in U.S. Pat. Nos. 8,906,724, 8,252,613, 9,698,314, US Publication No. 2016/0244663, US Publication No. 2018/0163126, and US Publication No. 2020/0369956. The entire contents of each of which are incorporated herein by reference. In one embodiment, the Mn⁴⁺ doped phosphors may be annealed, treated with multiple wash treatments and roasted.

To improve reliability, the Mn⁴⁺ doped phosphor of Formula I may be at least partially coated with surface coatings to enhance stability of the phosphor particles and resist aggregation by modifying the surface of the particles and increase the zeta potential of the particles. In one embodiment, the surface coatings may be a metal fluoride, silica or organic coating. In one embodiment, the red-emitting phosphors based on complex fluoride materials activated by Mn⁴⁺ phosphors are at least partially coated with a metal fluoride, which increases positive Zeta potential and reduces agglomeration. In one embodiment, the metal fluoride coating includes MgF₂, CaF₂, SrF₂, BaF₂, AgF, ZnF₂, AlF₃ or a combination thereof. In another embodiment, the metal fluoride coating is in an amount from about 0.1 wt % to about 10 wt %. In another embodiment, the metal fluoride coating is present in an amount from about 0.1 wt % to about 5 wt %. In another embodiment, the metal fluoride coating is present from about 0.3 wt % to about 3 wt %. Metal fluoride coated red-emitting phosphors based on complex fluoride materials activated by Mn⁴⁺ are prepared as described in WO 2018/093832, US Publication No. 2018/0163126 and US Publication No. 2020/0369956. The entire contents of each of which are incorporated herein by reference.

The phosphor material may include additional phosphors, such as an Yttrium Aluminum Garnet phosphor (YAG). The ratio of powders (YAG:PFS) may be tuned to reach a desired color point. The phosphor material may include additional phosphors, such as rare earth Garnet phosphors. The rare earth elements include: Sc, Y, La, Ce, Pr, Nd, Pm, Sm, Eu, Gd, Tb, Dy, Ho, Er, Tm, Yb and Lu. In one embodiment, the rare earth Garnet phosphor is an yttrium aluminum garnet phosphor (YAG). The ratio of the rare earth garnet phosphors to Mn⁴⁺ doped phosphor may be tuned to reach a desired color point.

The ink composition includes at least one binder material or at least one solvent. In some embodiments, the ink composition includes a binder material and a solvent.

The ink composition may include a binder material to further optimize the ink properties. A wide variety of binders and resin systems, with different chemistries and viscosities may be used.

In one embodiment, the binder matrix includes a crosslinked polymer. In another embodiment, the binder material includes curable materials, such as photocurable or UV-curable materials or thermally curable or thermoset binder materials or a combination. A thermally curable or thermoset binder material will polymerize or crosslink and form a cured resin binder matrix. Exemplary thermoset and UV binder materials include epoxy, acrylate, methacrylate, vinyl ester and siloxane families. Examples of suitable commercial resin systems include, but are not limited to a Pixelligent UVG Curable ink base, Optical Adhesive (Norland 68T), Pixelligent PixJet SFZ-1 with 40 wt % ZrO2 in acrylic formulation.

In one embodiment, the binder material may be present in an amount up to about 75 wt %. In another embodiment, the binder may be present in an amount up to about 70 wt %. In another embodiment, the binder may be present in an amount from about 5 wt % to about 75 wt %. In another embodiment, the binder is present in an amount of from about 10 wt % to about 70 wt %. In another embodiment, the binder is present from about 20 wt % to about 50 wt %. The weight % is based on total weight of the ink composition.

In another embodiment, the ink composition includes a first polymerization initiator and a second polymerization initiator for a 2-step curing process where during a first curing step in photo-initiated polymerization process is initiated by a radiation wavelength less than 400 nm (UV cure). The first polymerization initiator has a higher decomposition rate than the second polymerization initiator. The second curing process is free of UV radiation where the second polymerization initiator has a higher decomposition rate than the first polymerization initiator. The post cure phosphor treatment concentration increases by 5%, preferably 10%, and the print material decreases (shrinks) in volume by <20%, preferable <15%. The total print volume does not exceed 20 vol % shrinkage. The ink composition may include a solvent. The amount of solvent, solvent polarity, and solvent vapor pressure can aid in making a stable ink that meets viscosity, wettability, and optical density criteria of the ink composition. The solvent may be present in an amount effective for dissolving the phosphor material and any binder material and for adjusting the ink composition to a desired viscosity. In one embodiment, the solvent may be present from about 5 wt % to about 95 wt %. In another embodiment, the solvent may be present from about 10 wt % to about 75 wt %. In another embodiment, the solvent is present from about 20 wt % to about 50 wt %. The % wt of the solvent is based on the weight of the ink composition.

Phosphor particles can be formulated in inks using several solvent systems with demonstrated utility in the printing industry. Suitable solvents have a boiling point and polarity that match to the desired printing application and do not interact poorly with the binder material or phosphors used.

The solvents may be polar or non-polar. Examples of solvents include, but are not limited to acetone, glycol ethers, such as diethylene glycol methyl ether, propylene methyl acrylates, such as propylene glycol dimethyl acrylate, cyclic aromatic solvents, such as toluene, xylenes and anisol, aliphatic solvents, such as hexane and tetradecane, alcohols, such as ethanol, isopropanol, and octanol, glycols, such as ethylene glycol and propylene glycol, terpineol, acetates, such as butyl acetate, propylene glycol methyl ether acetate (PGMEA), N-methyl pyrrolidone (NMP), dimethyl sulfoxide (DMSO), dimethyl formamide (DMF), diethylene glycol methyl ether (DGME) and 2-(2-Butoxyethoxy)ethyl acetate (BEA).

Co-solvents and mixture of solvents can also be used to improve fluid, printing process and film forming properties. Mixture of solvents can be composed of any two or more of the solvents listed above and can also be comprised of small additions of common organic solvents into one of the solvents above.

The ink composition includes a phosphor material, which has a D50 particle size in a range from about 0.5 to about 15 microns. The particle sizes need to be small size for preparing ink compositions, for printing and for forming films. In another embodiment, the phosphor material includes a D50 particle size in a range from about 0.5 micron to about 10 microns. In another embodiment, the D50 particle size is in a range from about 0.5 micron to about 5 microns.

D50 (also expressed as D₅₀) is defined as the median particle size for a volume distribution. D90 or D₉₀ is the particle size for a volume distribution that is greater than the particle size of 90% of the particles of the distribution. D10 or D₁₀ is the particle size for a volume distribution that is greater than the particle size of 10% of the particles of the distribution. Particle size of the phosphors may be conveniently measured by laser diffraction or optical microscopy methods, and commercially available software can generate the particle size distribution and span. Span is a measure of the width of the particle size distribution curve for a particulate material or powder, and is defined according to the equation:

$$Span = \frac{( {D}_{90} - {D}_{10} )}{{D}_{50}}$$

wherein D₉₀, D₁₀ and D₅₀ are defined above. For phosphor particles, span of the particle size distribution is not necessarily limited and may be ≤1.0 in some embodiments.

The ink composition has a viscosity from about 10 cP to about 30,000 cP. In another embodiment, the viscosity is from about 1000 cP to about 30,000 cP.

In some embodiments, the ink composition is a low viscosity ink composition. The low viscosity ink composition includes a viscosity in the range of from about 10 cP to about 1000 cP. In another embodiment, the low viscosity ink composition has a viscosity in the range from about 10 cP to less than 1000 cP. It can be easier for particles to settle out of a low viscosity ink composition, so it is desired to include very small particle sizes of the phosphor material. Low viscosity ink compositions may be used in printing applications, such as banked structures or well structures.

In one embodiment, the ink composition is a medium viscosity ink composition. The medium viscosity ink composition includes a viscosity in a range from about 1000 cP to about 10,000 cP. In another embodiment, the viscosity is in a range from greater than 1000 cP to less than 10,000 cP.

In one embodiment, the ink composition is a high viscosity ink composition. The high viscosity ink composition includes a viscosity in a range from about 10,000 cP to about 30,000 cP. In another embodiment, the viscosity is in a range from greater than 10,000 cP to about 30,000 cP.

The viscosity ranges are for starting viscosity ranges in the ink composition.

Additional additives may be added to the ink composition to further tailor the ink properties or film properties, such as adhesion or cohesion, light scattering, evaporation rate, stability, shelf life, etc.

In one embodiment, the ink composition includes a scattering aid, such as ZrO₂ nanoparticles. Examples of scattering particles include, but are not limited to titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof. In other embodiments, additional additives improve film quality, such as Pentaerithritoltetrakis(3-mercaptopropionate) from Bruno Bock (BB PTh).

Additives may be added to the ink composition in an amount of from about 5 wt % to about 20 wt %, based on the weight of the ink composition.

External heating may be used to improve flowability of the ink composition, however, it should be noted that exceeding 65° C. for long periods of time may lead to premature curing.

The ink corporation is prepared using a solvent-based mixing and removal approach.

The phosphor and solvent or binder material are mixed until the phosphor is dispersed in the solvent, and partially removing the solvent. In some embodiments, the solvent is optional. Typically, the base ink, additive and a small amount of the solvent are mixed together and then the phosphor material is added in 2-4 increments with mixing in-between additions. Additional solvent may be needed to achieve the desired viscosity for good dispersion and coating.

When there is more than one phosphor, such as YAG. The second phosphor may be added first, followed by addition of the Mn⁴⁺ phosphor in ˜2 g increments. In one embodiment, the solution is vortexed between each powder addition. For example, the solution may be vortexed for 1 minute after each sample. In another embodiment, the mixture may be horn sonicated.

Once the particles are appropriately dispersed and homogenized, the solvent is partially removed. This process allows for incorporation of a high content of particles and gives the end user control over the viscosity by how much solvent remains in the final formulation.

In one embodiment, the suspension is subject to rotary evaporation until the desired amount of solvent is removed.

The ink solution may be cured after it has been applied in a printing technique described herein. The ink solution may also be coated onto a substrate or formed into a film. In one embodiment, the ink composition is subject to a suitable temperature for heat curing or to a suitable radiation wavelength for UV curing, such as less than 400 nm.

In one embodiment, a 2-step cure utilizing UV and thermal cure is applied to the ink composition. This system simultaneously contains both photosensitive groups and thermosensitive groups. The first curing process utilizes a UV cure to soft cure the material in place. The wavelength for polymerization initiation is less than 400 nm (to classify as UV cure). The second curing step is a thermal cure, which uses heat to initiate the remainder of the polymerization reaction. The second curing step acts as a binding or through-cure mechanism. In a film, the second step may reduce the volume of the deposited film through shrinkage.

The advantage of the 2-step cure approach for curing a film is that it can tune how much and at what point in the process the deposited film shrinks. Depending on the content of each polymerization initiator, concentration of PFS can be tailored through altering the film densification mechanism. A UV only curing system relies on UV radiation touching every surface and one cannot assume the curing of shadowed or deep areas. Thermal only cure is not typically fast and therefore “slumping” or segregation/skinning can occur in deposited inks. Using a UV cure to “soft cure” followed by a thermal cure to “through-cure” the shape or film can be envisioned.

The 2-step curing approach can also be used to form 1 feature over another cured feature by UV cure, followed by thermal cure to further “bond” the two layers together.

The phosphor material may include, one or more other luminescent materials. Additional luminescent materials, such as blue, yellow, red, orange, or other color phosphors may be used in the phosphor material to customize the white color of the resulting light and produce specific spectral power distributions.

Suitable phosphors for use in the phosphor material, include, but are not limited to: ((Sr_{1-z}[Ca,Ba,Mg,Zn]_{z})_{1-(x|w)}[Li,Na,K,Rb]_{w}Ceₓ)₃(Al_{1-y}Si_{y})O_{4|y|3(x-w)}F_{1-y-3(x-w)}, 0<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺,Mn²⁺; └Ba,Sr,Ca┘BPO₅:Eu²⁺,Mn²⁺; └Sr,Ca┘₁₀(PO₄)₆*vB₂O₃:Eu²⁺ (wherein 0≤v≤1); Sr₂Si₃O₈*2SrCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]₅₋ₐO_{12-3/2a}:Ce³⁺ (wherein 0≤a≤0.5); [Ca,Sr]₈[Mg,Zn](SiO₄)₄Cl₂:Eu²⁺,Mn²⁺; Na₂Gd₂B₂O₇:Ce³⁺,Tb³⁺; [Sr,Ca,Ba,Mg,Zn]₂P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO₆:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (where 0.5≤u≤1, 0<v≤0.1, and 0≤w≤0.2); [Y,Lu,Gd]₂₋ₘ [Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺; 3.5MgO*0.5MgF₂*GeO₂:Mn⁴⁺; Ca_{1-c-f}Ce_{c}Eu_{f}A_{1+c}Si_{1-c}N₃, (where 0≤c≤0.2, 0≤f≤0.2); Ca₁₋ₕ₋ᵣCeₕEuᵣAl₁₋ₕ(Mg,Zn)ₕSiN₃, (where 0≤h≤0.2, 0≤r≤0.2); Ca₁₋₂ₛ₋ₜCeₛ[Li,Na]ₛEuₜAlSiN₃, (where 0≤s≤0.2, 0≤t≤0.2, s+t>0); [Sr, Ca]AlSiN₃; and Eu^{2|},Ce^{3|}, Li₂CaSiO₄:Eu^{2|}.

In particular embodiments, additional phosphors include: [Y,Gd,Lu,Tb]₃[Al,Ga]₅O₁₂:Ce^{3|}, β-SiAlON:Eu^{2|}, [Sr,Ca,Ba][Ga,Al]₂S₄:Eu^{2|}, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, and [Ba,Sr,Ca]₂Si₂O₄:Eu²⁺.

The phosphor material may include at least one green-emitting phosphor. The green-emitting phosphor may include any suitable green-emitting phosphors, including a uranium phosphor. In one embodiment, green-emitting uranium phosphors include, but are not limited to Ba₃(PO₄)₂(UO₂)₂P₂O₇, Ba₃(PO₄)₂(UO₂)₂V₂O₇, gamma γ-Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂, K₄UO₂(VO₄)₂, or NaUO₂P₃O₉, as described in U.S. Pat. No. 11,254,864, and incorporated herein.

Other additional luminescent materials suitable for use in the ink composition may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADS090GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

Exemplary QD materials include, but are not limited to, group II-IV compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III—V or group IV-VI compound semiconductors such as GaN, GaP, GaNP, GaNAs, GaPAs, GaAs, GaAlNP, GaAlNAs, GaAlPAs, GaInNP, GaInNAs, GaInPAs, AlN, AlNP, AlNAs, AlP, AlPAs, AlAs, InN, InNP, InP, InNAs, InPAs, InAS, InAlNP, InAlNAs, InAlPAs, PbS/ZnS or PbSe/ZnS, group IV, such as Si, Ge, SiC, and SiGe, chalcopyrite-type compounds, including, but not limited to, CuInS₂, CuInSe₂, CuGaS₂, CuGaSe₂, AgInS₂, AgInSe₂, AgGaS₂, AgGaSe₂ or perovskite QDs having a formula of ABX₃ where A is cesium, methylammonium or formamidinium, B is lead or tin and C is chloride, bromide or iodide. The quantum dot material may include core-shell nanostructures having an Ag—In—Ga—S (AIGS) core and an Ag—Ga—S (AGS) shell.

In one embodiment, the perovskite quantum dot may be CsPbX₃, where X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, [Al, Ga, In]₂[S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

The ratio of each of the individual phosphors and other luminescent materials in the ink composition may vary depending on the characteristics of the desired light output. The relative proportions of the individual phosphors and other luminescent materials in the various ink compositions may be adjusted such that when their emissions are blended and employed in a device, for example a lighting apparatus, there is produced visible light of predetermined x and y values on the CIE chromaticity diagram.

In one embodiment, films may be prepared from the ink compositions. The films may be deposited on substrates, such as glass substrates. Films may be deposited on LEDs, such as mini-LEDs or micro-LEDs, such as by coating, using a doctors bade or by printing. In one embodiment, a film is prepared by coating the ink composition on a glass substrate with a doctors blade. The solvent may be removed, and the film is cured, such as by UV light or heat curing.

Additional processes for preparing phosphor compositions which may be used with the systems and methods described herein are described in PCT Application No. [INSERT APPLICATION NUMBER], titled [INSERT TITLE] filed on May 4, 2023, which incorporated by reference in its entirety.

In one embodiment, a lighting apparatus includes the device. In another embodiment, a backlight apparatus includes the device. In another embodiment, a display includes the device. In another embodiment, the device is a self-emissive display and does not contain a liquid crystal display (LCD). In one embodiment, the display is a micro-LED display, such as a phosphor-converted micro-LED display.

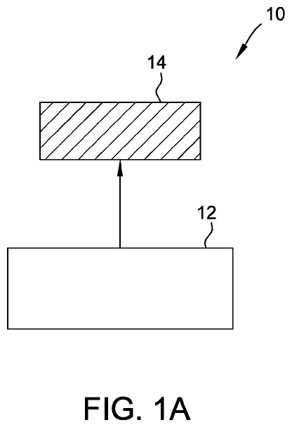

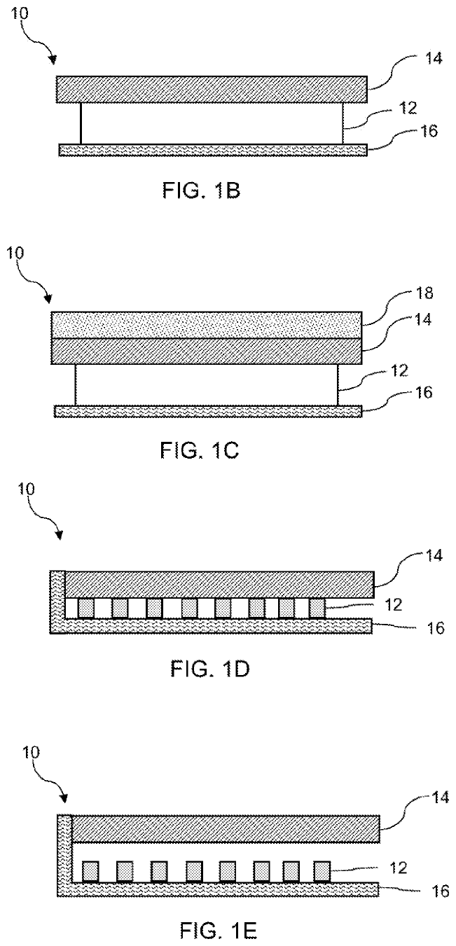

Devices according to the present disclosure include an LED light source radiationally connected and/or optically coupled to the phosphor composition. FIGS. 1A-1E show a device 10, according to various embodiments of the present disclosure. Referring to FIG. TA, the device 10 includes an LED light source 12 and the phosphor composition 14. The LED light source 12 may be a UV or blue emitting LED. In some embodiments, the LED light source 12 produces blue light in a wavelength range from about 380 nm to about 460 nm. In the device 10, the phosphor composition 14 is radiationally coupled and/or optically coupled to the LED light source 12. Radiationally connected or coupled or optically coupled means that radiation from the LED light source 12 is able to excite the phosphor composition 14, and the phosphor composition 14 is able to emit light in response to the excitation by the radiation. The phosphor composition 14 may be disposed on a part or portion of the LED light source 12 or located remotely at a distance from the LED light source 12. In some embodiments, the device may be a backlight unit for display applications. In other embodiments, the LED light source 12 is a micro-LED and the device is for a self-emissive display. FIG. 1B shows an exemplary embodiment where the phosphor composition 14 is disposed on the LED light source 12. The LED light source 12 is disposed on a reflective layer 16. The reflective layer 16 reflects light from the LED light source 12 toward the LED light source and the phosphor composition 14. The reflective layer 16 may be any material suitable for reflecting light. In one embodiment, the reflective layer 16 may be a metallic layer, such as aluminum, silver, silver alloys or aluminum alloys. FIG. 1C shows an exemplary embodiment where the phosphor composition 14 is disposed on the LED light source 12. An encapsulant or barrier layer 18 is disposed on the phosphor composition 14. The encapsulant or barrier layer 18 may be a low temperature glass, or a polymer or resin known in the art, for example, an epoxy, silicone, epoxy-silicone, acrylate or a combination thereof. The encapsulant or barrier layer 18 should be transparent to allow light to be transmitted through those elements. FIG. 1D shows an exemplary embodiment where the LED light source 14 is depicted as an array of LED light sources 12. In some embodiments, the LED light sources 12 are mini-LEDs or micro-LEDs. FIG. 1E shows an exemplary embodiment where the phosphor composition 14 is located remotely from the LED light source 12, which is depicted as an array of LED light sources 12.

The general discussion of the example LED light source discussed herein is directed toward an inorganic LED based light source. The most popular white LEDs are based on blue or UV emitting GaInN chips. In addition, to inorganic LED light sources, the term LED light source is meant to encompass all LED light sources, such as semiconductor laser diodes (LD), organic light emitting diodes (OLED) or a hybrid of LED and LD. The LED light source may be a mini-LED or micro-LED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

The phosphor composition 14 may be present in any form such as powder, glass, or composite e.g., phosphor-polymer composite or phosphor-glass composite. Further, the phosphor composition 14 may be used as a layer, sheet, film, strip, dispersed particulates, or a combination thereof. In some embodiments, the phosphor composition 14 includes the uranium-based phosphor material in glass form. In some of these embodiments, the device 10 may include the phosphor composition 14 in form of a phosphor wheel (not shown). The phosphor wheel may include the phosphor composition embedded in a glass. A phosphor wheel and related devices are described in WO 2017/196779.

The phosphor composition is optically coupled or radiationally connected to an LED light source. In one embodiment, a white light blend may be obtained by blending the red phosphor material and the green phosphor material with an LED light source, such as a blue or UV LED.

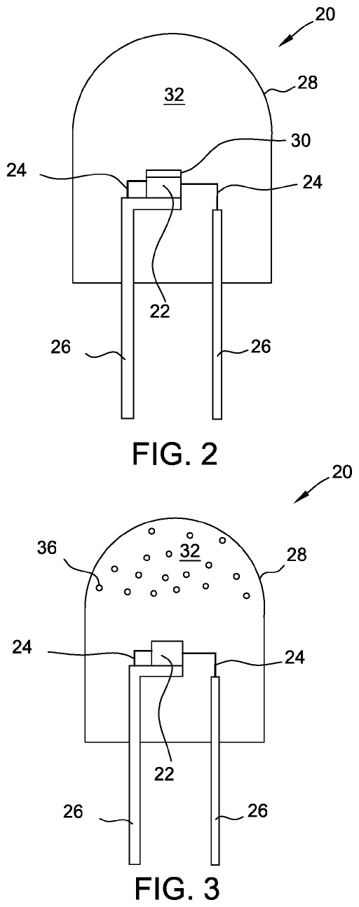

FIG. 2 illustrates alighting apparatus or lamp 20, in accordance with some embodiments. In one embodiment, the lighting apparatus 20 may be a backlight apparatus. The lighting apparatus 20 includes an LED chip 22 and leads 24 electrically attached to the LED chip 22. The leads 24 may comprise thin wires supported by a thicker lead frame(s) 26 or the leads 24 may comprise self-supported electrodes and the lead frame may be omitted. The leads 24 provide current to LED chip 22 and thus cause it to emit radiation.

A layer 30 of the phosphor composition is disposed on a surface of the LED chip 22. The phosphor layer 30 may be disposed by any appropriate method, for example, using a slurry or ink composition prepared by mixing the phosphor composition and a binder material or solvent (as discussed above). In one such method, a silicone slurry in which the phosphor composition particles are randomly suspended or uniformly dispersed is placed around the LED chip 22. This method is merely exemplary of possible positions of the phosphor layer 30 and LED chip 22. The phosphor layer 30 may be coated over or directly on the light emitting surface of the LED chip 22 by coating and drying the slurry over the LED chip 22. The light emitted by the LED chip 22 mixes with the light emitted by the phosphor composition to produce desired emission.

With continued reference to FIG. 3, the LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

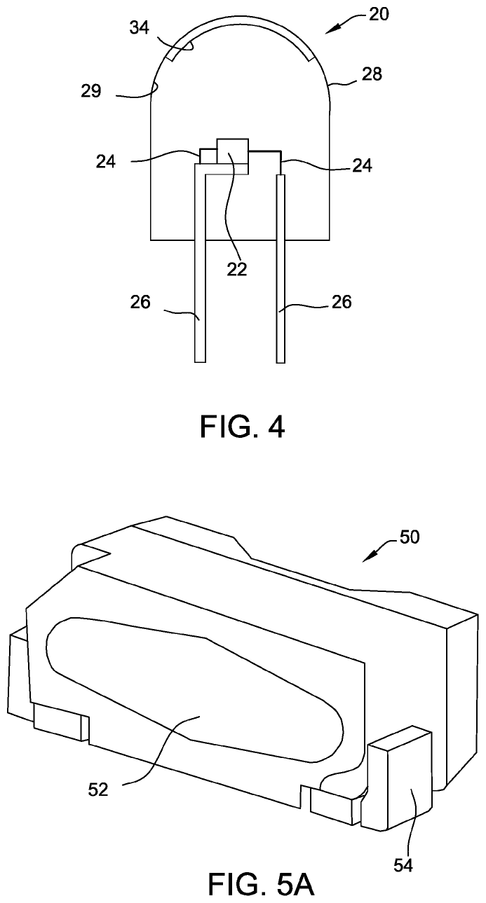

In some embodiments as illustrated in FIG. 3, the phosphor composition 33 is interspersed within the encapsulant material 32, instead of being formed directly on the LED chip 22, as shown in FIG. 4. The phosphor composition 33 may be interspersed within a portion of the encapsulant material 32 or throughout the entire volume of the encapsulant material 32. Blue light or UV light emitted by the LED chip 22 mixes with the light emitted by phosphor composition 33, and the mixed light transmits out from the lighting apparatus 20.

In yet another embodiment, a layer 34 of the phosphor composition is coated onto a surface of the envelope 28, instead of being formed over the LED chip 22, as illustrated in FIG. 4. As shown, the phosphor layer 34 is coated on an inside surface 29 of the envelope 28, although the phosphor layer 34 may be coated on an outside surface of the envelope 28, if desired. The phosphor layer 34 may be coated on the entire surface of the envelope 28 or only a top portion of the inside surface 29 of the envelope 28. The UV/blue light emitted by the LED chip 22 mixes with the light emitted by the phosphor layer 34, and the mixed light transmits out. Of course, the phosphor composition may be located in any two or all three locations (as shown in FIGS. 4-6) or in any other suitable location, such as separately from the envelope 28, remote or integrated into the LED chip 22. In one embodiment, the phosphor layer 34 may be a film and located remotely from the LED chip 22. In another embodiment, the phosphor layer 34 may be a film and disposed on the LED chip 22. In some embodiments, the phosphor layer 34 may be applied to the LED chip 22 as an ink composition. In some embodiments, the phosphor layer 34 may be applied to the LED chip 22 as an ink composition and dried to form a film on the LED chip 22. In some embodiments, the phosphor composition may be a single layer or multi-layered. In some embodiments, the film is a multi-layered structure where each layer of the multi-layered structure includes at least one phosphor or quantum dot material. In another embodiment, a device structure includes a layer of a phosphor composition on an LED chip and a remote layer including a quantum dot material. In another embodiment, a device structure includes a layer of a phosphor composition on an LED chip and a remote layer including a quantum dot material and phosphor material. In another embodiment, a device structure includes a layer of a phosphor composition on an LED chip and a film including quantum dot material located remotely from the LED chip. In another embodiment, a device structure includes a layer of a phosphor composition on an LED chip and a film including quantum dot material and phosphor material located remotely from the LED chip.

In any of the above structures, the lighting apparatus 20 (FIGS. 1-4) may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

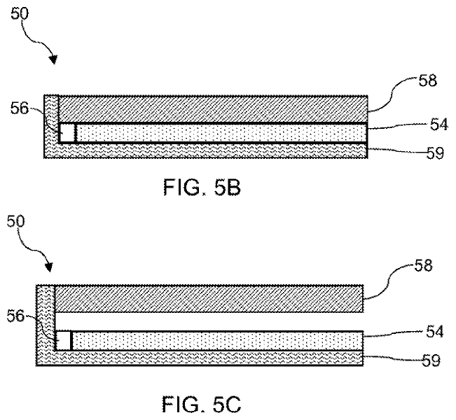

In one embodiment, the lighting apparatus 20 shown in FIG. 3 or FIG. 4 may be a backlight apparatus. In another embodiment, the backlight apparatus comprises a backlight unit 10. Some embodiments include a surface mounted device (SMD) type light emitting diode 50, e.g., as illustrated in FIGS. 5A, 5B and 5C, for backlight applications. Referring to FIG. 5A, SMD is a “side-emitting type” and has a light-emitting window 52 on a protruding portion of a light guiding member 54. An SMD package comprises an LED chip 56 as defined above, and a phosphor composition 58 as described herein. FIG. 5B shows the phosphor composition 58 disposed on the LED chip 56 and FIG. 5C shows the phosphor composition 58 disposed remotely from the LED chip 56. FIGS. 5B and 5C also show the LED chip 56 and the light guiding member 54 disposed on a reflective layer 59. The reflective layer 59 reflects light from the LED chip 56 and the light guiding member 54 toward the phosphor composition 58. The reflective layer 59 may be any material suitable for reflecting light. In one embodiment, the reflective layer 59 may be a metallic layer, such as a silver, aluminum, aluminum alloy or silver alloy. In another embodiment, the device may be a direct lit display.

By use of the phosphor compositions described herein, devices can be provided producing white light for display applications, for example, LCD backlight units, having high color gamut and high luminosity. Alternately, devices can be provided producing white light for general illumination having high luminosity and high CRI values for a wide range of color temperatures of interest (2000 K to 10,000 K).

Devices of the present disclosure include lighting and display apparatuses for general illumination and display applications. Examples of display apparatuses include liquid crystal display (LCD) backlight units, televisions, computer monitors, vehicular displays, laptops, computer notebooks, mobile phones, smartphones, tablet computers and other handheld devices. Where the display is a backlight unit, the phosphor composition may be incorporated in a film, sheet or strip that is radiationally coupled and/or optically coupled to the LED light source, as described in US Patent Application Publication No. 2017/0254943. Examples of other devices include chromatic lamps, plasma screens, xenon excitation lamps, UV excitation marking systems, automotive headlamps, home and theatre projectors, laser pumped devices, and point sensors. In one embodiment, the device may be a fast response display that does not include an LCD. The fast response display may be a self-emissive display including phosphor converted (PC) micro-LEDs. The list of these applications is meant to be merely exemplary and not exhaustive.

In some embodiments, films including the phosphor composition may be disposed on small-size LEDs, such as micro-LEDs or mini-LEDs. In other embodiments, the film includes phosphors with micron or sub-micron particle sizes. In other embodiments, the film includes nano-sized particles. In one embodiment, the film includes a Mn⁴⁺ doped phosphor having a D50 particle size less than 20 μm, less than 10 μm, particularly less than 5 μm, more particularly nano-sized. In another embodiment, the D50 particle size may be from about 1 micron to about 20 microns. In another embodiment, the D50 particle size is from about 1 micron to about 15 microns. In another embodiment, the D50 particle size is from about 1 micron to about 10 microns. In another embodiment, the D50 particle size is from about 1 micron to about 5 microns. In another embodiment, the D50 particle size is from about 1 micron to about 3 microns. In another embodiment, the D50 particle size is from about 50 nm to about 1000 nm. In another embodiment, the D50 particle size is from about 100 nm to about 1000 nm. In another embodiment, the D50 particle size is from about 200 nm to about 1000 nm. In another embodiment, the D50 particle size is from about 250 nm to about 1000 nm. In another embodiment, the D50 particle size is from about 500 nm to about 1000 nm. In another embodiment, the D50 particle size is from about 750 nm to about 1000 nm. In another embodiment, the D50 particle size is from about 50 nm to about 10 microns. In another embodiment, the D50 particle size is from about 200 nm to about 5 microns. In another embodiment, the D50 particle size is from about 250 nm to about 5 microns. In another embodiment, the D50 particle size is from about 500 nm to about 5 microns. In another embodiment, the D50 particle size is from about 750 nm to about 5 microns. In another embodiment, the D50 particle size is from about 750 nm to about 3 microns.

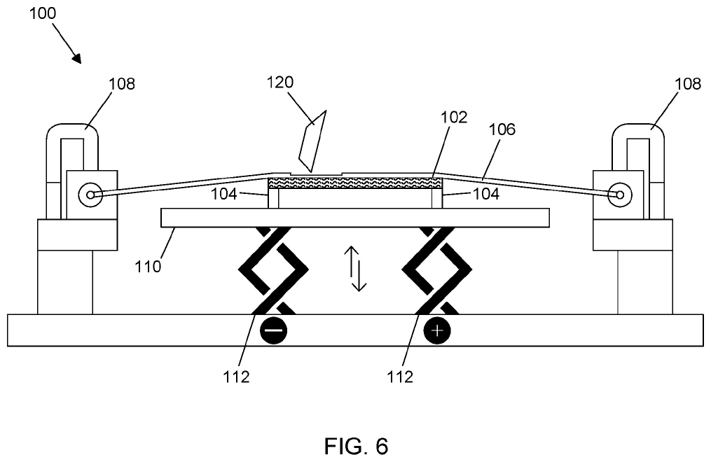

FIG. 6 is a schematic diagram of a contact stencil printing system 100, in accordance with one embodiment of the disclosure. Contact stencil printing system 100 may be used to deposit a composition, such as a phosphor ink, onto a target substrate comprising a plurality of light emitting elements, including, but not limited to, LEDs, mini-LEDs, OLEDs or micro-LEDs.

Contact stencil printing system 100 may comprise a substrate 102, substrate supports 104, a stencil 106, stencil frame grips 108, and alignment adjusters 112. Stencil 106 may be fabricated on flexible 2 mil, 3 mil, and 5 mil polyimide substrates. These thicknesses are provided by way of example only, and various other thicknesses may be used. In some embodiments, stencil 106 is fabricated from a polyimide substrate manufactured by Kapton® or Upilex®.

Stencil 106 comprises one or more openings. The one or more openings may comprise various shapes (e.g., circular, rectangular, square, or any other shape) of dimensions as small as 25 μm in width and/or length. The one or more openings may be made via a laser cutting tool and may comprise various patterns, lengths, widths, and orientations. For example, The configuration of the one of more openings may consider parameters of the composition being deposited, including but not limited to viscosity, wettability, solvent type, quantity, epoxy/emulsion type, and/or PFS to YAG ratio of the composition.

Stencil 106 may be held in place by a plurality of stencil frame grips 108. Stencil 106 is placed over substrate 102, which is supported by a plurality of supports 104. Substrate 102 and supports 104 may be located on an adjustable surface 110. Adjustable surface 110 may be adjusted in a vertical direction via alignment adjusters 112. More specifically, alignment adjusters may be configured to adjust a location of substrate 102 with respect to stencil 106 such that stencil 106 comes into contact with substrate 102.

In some embodiments, composition transfer using stencil printing system 100, occurs as a result of movement of a squeegee 120 across stencil 106, and simultaneously, squeegee 120 pressing down on stencil 106, thereby causing stencil 106 to make contact with substrate 102. Printing speed (e.g., the squeeze movement on stencil) is important, as slow printing results more and/or wider transfer of material as stencil remains in touch with substrate for longer time and faster printing speed results more controlled transfer of material due to its small time-period interaction between the substrate and stencil.

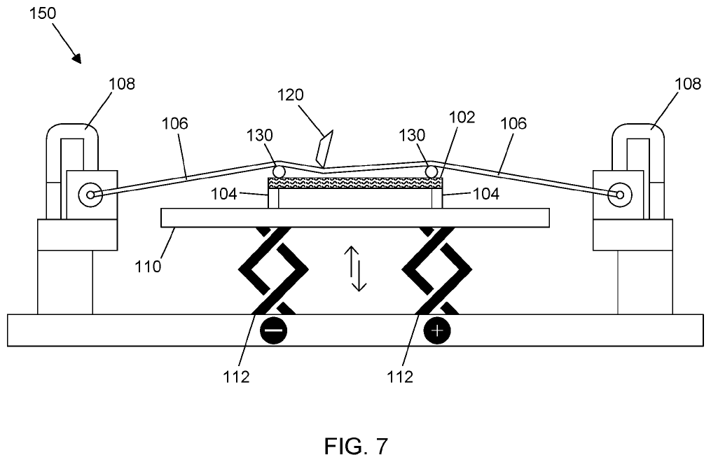

FIG. 7 is a schematic diagram of a snap-off stencil printing system 200, in accordance with one embodiment of the disclosure. Snap-off stencil printing system 200 may be used to deposit a composition, such as a phosphor ink, onto a target substrate, such LEDs, mini-LEDs, OLEDs or micro-LEDs. Stencil 106 may be fabricated on flexible 2 mil, 3 mil, and 5 mil polyimide substrates. These thicknesses are provided by way of example only, and various other thicknesses may be used. In some embodiments, stencil 106 is fabricated from a polyimide substrate manufactured by Kapton®, or Upilex®.

Stencil 106 comprises one or more openings. The one or more openings may comprise various shapes (e.g., circular, rectangular, square, or any other shape) of dimensions as small as 25 μm in width and/or length. The one or more openings may be made via a laser cutting tool and may comprise various patterns, lengths, widths, and orientations. The configuration of the one of more openings may consider parameters of the composition being deposited, including but not limited to viscosity, wettability, solvent type, quantity, epoxy/emulsion type, and/or PFS to YAG ratio of the composition.

Similar to contact stencil printing system 100, snap-off stencil printing system 200 may comprise a substrate 102, substrate supports 104, a stencil 106, stencil frame grips 108, and alignment adjusters 112. Stencil 106 may be held in place by a plurality of stencil frame grips 108. Stencil 106 is placed over substrate 102, which is supported by a plurality of supports 104. Substrate 102 and supports 104 may be located on an adjustable surface 110. Adjustable surface 110 may be adjusted in a vertical direction via alignment adjusters 112. More specifically, alignment adjusters may be configured to adjust a location of substrate 102 with respect to stencil 106 such that stencil 106 comes into contact with substrate 102. Printing speed (e.g., the squeeze movement on stencil) is important, as slow printing results more and/or wider transfer of material as stencil remains in touch with substrate for longer time and faster printing speed results more controlled transfer of material due to its small time-period interaction between the substrate and stencil.

However, printing system 200 further comprises one or more snap-offs or spacers 130. Spacers 130 are located between substrate 102 and stencil 106 thereby separating substrate 102 and stencil 106 by a distance. In general, the farther away the spacers 130 are from substrate 110, the smaller the difference between the contact angle between stencil openings and substrate 110, thereby enabling better printing uniformity over large printing area. Composition transfer using stencil printing system 200 also occurs as a result of movement of a squeegee 120 across stencil 106, and simultaneously, squeegee 120 pressing down on stencil 106, thereby causing stencil 106 to make contact with substrate 102.

In an exemplary embodiment, stencil 106 is stretched uniformly over substrate 102. In some embodiments, stencil 106 is cut shorter than the stencil's frame stretching limit. Cutting stencil 106 shorter than the stencil's frame stretching limit helps eliminate bulges which may result in non-uniform printing. For example, in some embodiments, stencil 106 is stretched to an upper limit of stencil frame grips 108. This may result in stencil 106 being stretched uniformly over the entire stencil area without any bulges, which would result in non-uniform printing. In some embodiments, an adhesive, such as tape is attached to one or more edges of stencil 106, so that stencil 102 is stretched even further, thereby removing any remining bulges and/or waviness in the stencil. In some embodiments, the adhesive comprises a polyamide tape.

In some embodiments, a calibration is performed before a composition transfer. More particularly, spacers 130 introduce a mismatch between a stencil opening and a target printing point. The calibration ensures that there is proper alignment between the stencil opening and the target printing point.

In some embodiments, multi-pass printing may be used to build printed ink height and/or increase the aspect ratio over the targeted printing area. While spacers 130 of snap-off stencil printing system 200 provide controlled and precise transfer of ink, non-snap-off printing (e.g., printing using contact stencil printing system 100) results in high volume ink transfer. In some embodiments, snap-off printing (e.g., using snap-off stencil printing system 200) is followed by non-snap-off printing (e.g., printing using contact stencil printing system 100) may be used to build material height and/or increase the aspect ratio over the targeted printing area. The snap-off printing may transfer a controlled amount of ink to build an ink base over which more material can be transferred using non-snap-off printing. Using the same material base provides better wettability of a subsequent print run, resulting in better ink transfer and more height.

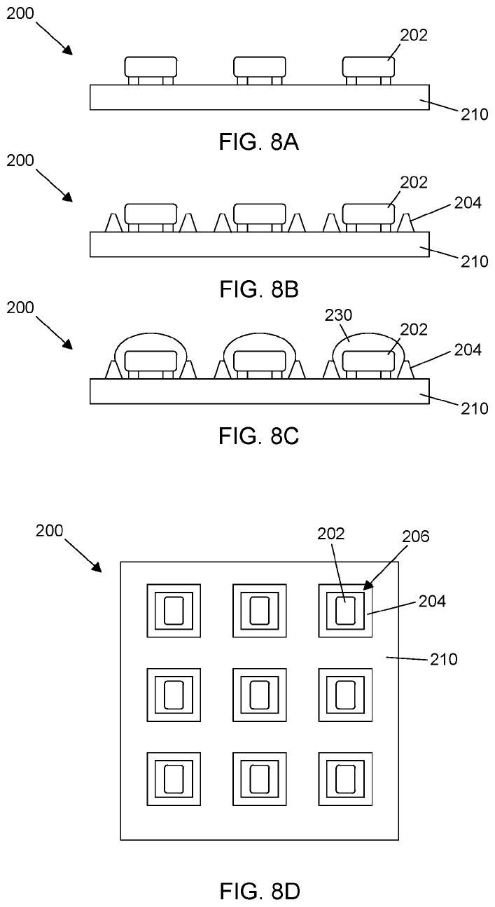

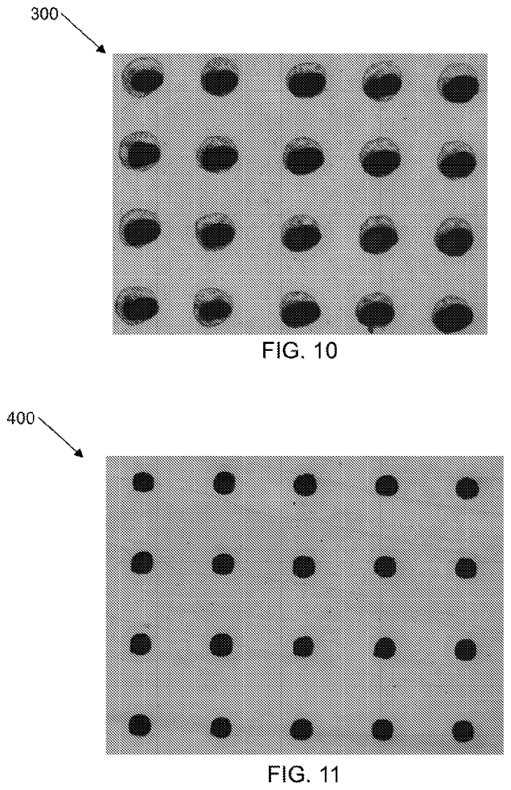

FIGS. 8A-8C are schematic diagrams of a banked arrangement 200, in accordance with an embodiment of the disclosure. More particularly, FIGS. 10A-10C illustrate banked arrangement 200 at different phases of a dispensing or printing process. Both printing and transferring a high aspect ratio conversion layer on small-feature light emitting elements (e.g., mini-LEDs, and/or micro-LEDs) assembled over a plain substrate surface is challenging. Banked arrangement 200 enables a high aspect ratio conversion layer to be achieved on small-feature light emitting elements in a more efficient and cost-effective manner than current printing and/or dispensing technologies. For example, in some embodiments, an aspect ratio of at least 0.1 (i.e., 1:10) may be achieved. In another embodiment, the aspect ratio is from about 0.1 to about 10. In another embodiment, the aspect ratio is from about 0.1 to 5. In another embodiment, the aspect ratio is from about 0.5 to 5. In another embodiment, the aspect ratio is from about 0.1 to 3, more particularly, 0.1 to 1 and 0.1 to 0.5.

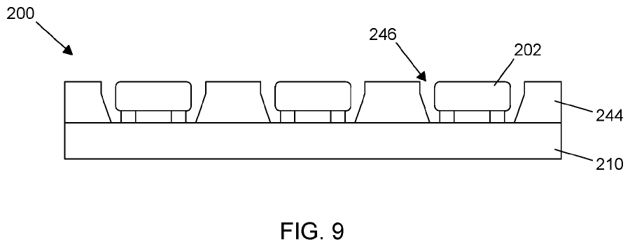

In FIG. 8A a plurality of light emitting elements 202 (e.g., LEDs, mini-LEDs, and/or micro-LEDs), operating at a desired color point (e.g., white light) are disposed on a substrate 210. In FIG. 8B, one or more walls 204 are disposed around each of the plurality of light emitting elements 202. In some embodiments, each light emitting element 202 is surrounded by continuous walls 204. For example, each light emitting element 202 is surrounded by a plurality of walls 204 which form a closed square, rectangle, or other shape, thereby forming a banked structure around each light emitting element 202. In the embodiment illustrated in FIGS. 8A-8D, each light emitting element 202 is surrounded by four walls 204 formed on planar structure 210, which form a banked structure 206. In other embodiments, such as the embodiment illustrated in FIG. 9, walls 204 are formed within a layer 244 that sits on top of the planar substrate 210, thereby forming a well structure 246. Therefore, banked arrangement 200 may comprise each light emitting element 202 surrounded by a banked structure 206 or a well structure 246. In some embodiments, banked structure 206 or well structure 246 is formed via printing (e.g., using contact stencil printing system 100 of FIG. 6 or snap-off stencil printing system 200 of FIG. 7). In further embodiments, snap-off printing is desired, as it provides control over printing speed and with the appropriate opening dimensions, may lead to the right amount of material at the desired positioning to be transferred to fill well structures without any spill over to next pixel/color-filters. Further, in some embodiments comprising well structure, a relatively thin stencil thickness may be used for better see-through to assist with alignment at a micron scale.

In some embodiments, walls 204 are comprised of a reflective materials, and therefore may act as reflectors. More particularly, walls 204 are coated with a white surface which reflects back all the visible wavelengths that shine on it. The reflective material in walls 204 may increase the brightness of the light emitting elements. In some embodiments, one or more walls 204 are comprised of a translucent material For example, in transparent display applications, walls 204 may be comprised of a translucent material.

In FIG. 8C, the banked structure, or alternatively the well structure, is filled with an optically active material 230. The optically active material may include a down-conversion material, such as a phosphor material. In some embodiments the banked structure, or alternatively, the well structure, is filled by a dispensing and/or printing method. For example, in some embodiments, the banked structure or the well structure is filled using contact stencil printing system 100 of FIG. 6 or snap-off stencil printing system 200 of FIG. 7. Snap-off stencil printing system 200 enables the transfer of materials with high reproducibility and uniformity in a cost-effective manner. In other embodiments, the well is filled via dispensing or printing methods known in the art.

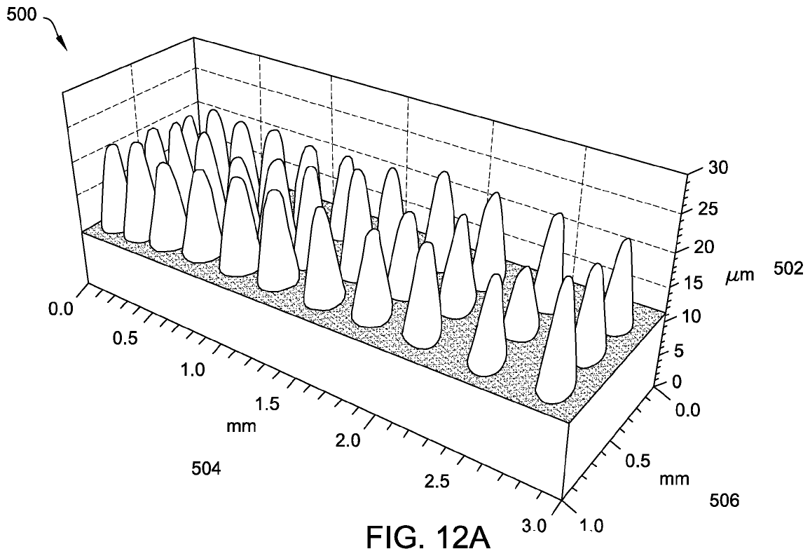

FIG. 10 is a composition deposited on a substrate 300 using contact stencil printing system 100 and FIG. 11 is a composition deposited on a substrate 400 using snap-off stencil printing system 200. In both FIG. 10 and FIG. 11, a 3-mil stencil with 120 μm square openings with a 450 μm pitch was used. As compared to contact stencil printing system 100, snap-off stencil printing system 200 enables a higher amount of composition transfer to a surface of substrate 102. More particularly, the distance between substrate 102 and stencil 106 introduced by spacers 130 helps remove the stencil openings after the composition has been transferred, leading to a defined transfer of composition. This may result in a high aspect ratio (height to width) to the substrate. A high aspect ratio is desirable, as a relatively high height is needed to convert blue light emitted from a blue light source such as OLED, LED, mini-led, or micro-LED, or potentially a UV light source, to red light.

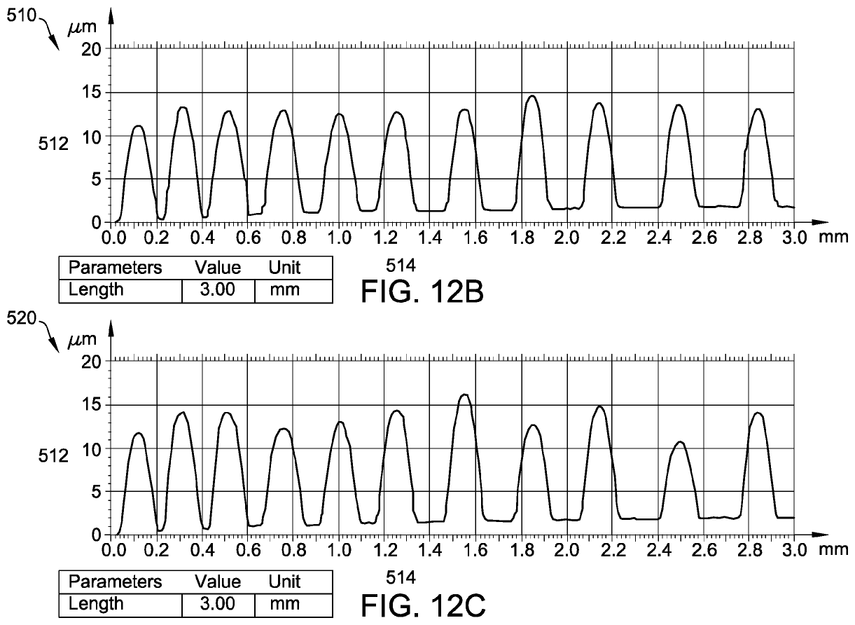

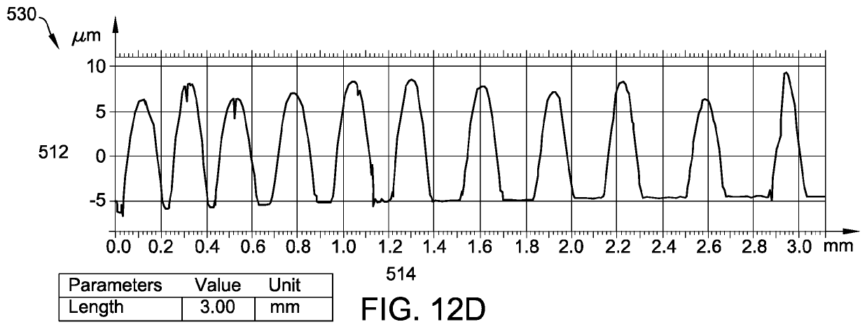

FIGS. 12A and 12B comprise graphs representing the aspect ratio of a printed ink composition pattern deposited using snap-off stencil printing. More particularly, FIG. 12A is a three-dimensional graph 500 illustrating the height 506, and depth 506 of each of the deposited ink compositions along a width 504 of a substrate. Similarly, FIG. 12B illustrates the height 512 of each of the deposited ink compositions along the width 514 of a substrate. As can be gleaned from FIGS. 12A and 12B, a relatively high aspect ratio may be achieved in a reproducible manner using snap-off stencil printing. In the example illustrated in FIG. 12A, an aspect ratio of 0.1 is achieved. In another embodiment, the aspect ratio is from about 0.1 to about 10. In another embodiment, the aspect ratio is from about 0.1 to 5. In another embodiment, the aspect ratio is from about 0.5 to 5. In another embodiment, the aspect ratio is from about 0.1 to 3, more particularly, 0.1 to 1 and 0.1 to 0.5.

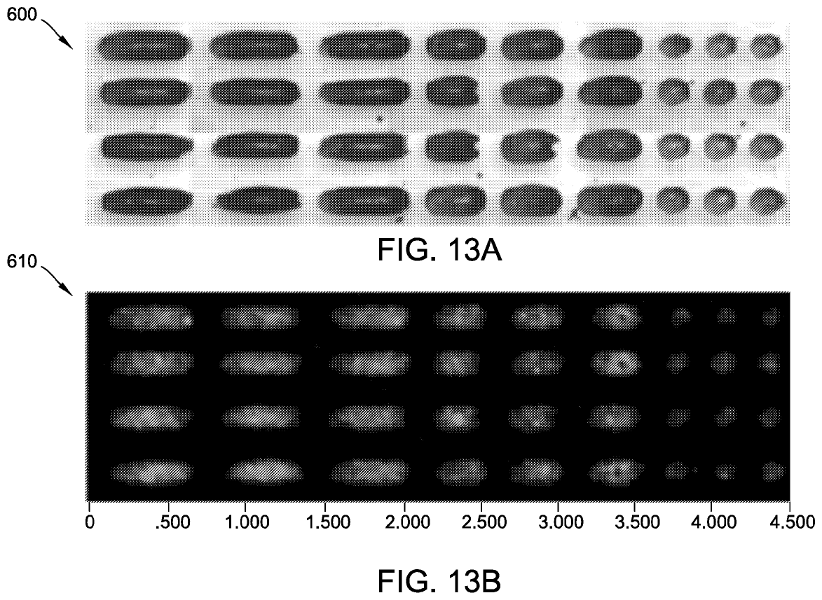

FIG. 13A illustrates printed ink composition pattern 600 deposited via snap-off stencil printing using 2 mil stencil and FIG. 13B is a photoluminescence intensity map 610 of the pattern 600 under optical excitation of 457 nm and emission intensity of 630 nm. As clearly illustrated in FIGS. 13A and 13B, the snap-off stencil printing deposited the ink composition only where intended, and did not result in any spill over.

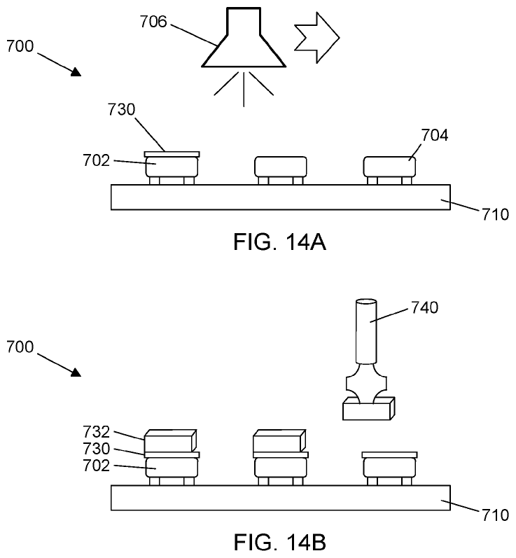

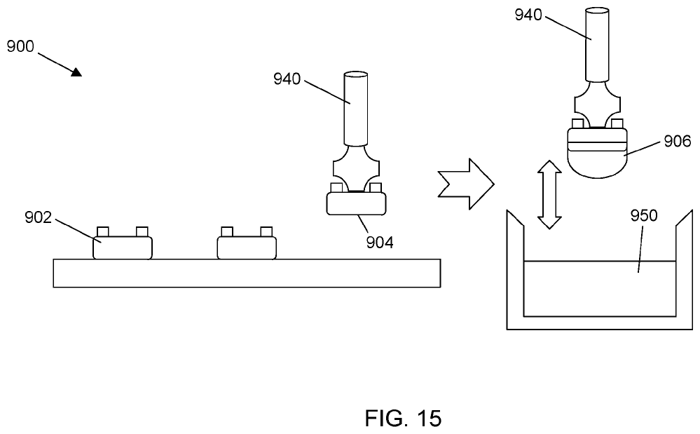

FIGS. 14A and 14B are schematic diagrams of a high precision pick and place system 700 in accordance with an embodiment of the present disclosure. More particularly, FIGS. 14A and 14B illustrate pick and place arrangement 700 at different phases of a high precision and resolution pick and place process. The process illustrated in FIGS. 14A and 14B may be used for both assembled LED panels and individual LEDs prior to assembly.

In FIG. 14A, light emitting elements 702 are disposed on substrate. FIG. 14A illustrates preparing an emitting surface 704 of each light emitting element 702. More particularly, each emitting surface 704 is coated with an optical adhesive 730. In the embodiment illustrated in FIG. 14A, optical adhesive 730 is disposed on emitting surface 704 via spray coating using spray nozzle 706. However, optical adhesive 730 may be disposed on emitting surface 704 via dispensing or other method known in the art.

FIG. 14B illustrates the depositing of an optically active film 730 (e.g., a film containing phosphor materials) on each emitting surface 704 coated with optical adhesive 730. The optically active film 730 may be sized and shaped for emitting surface 704. For example, prior to assembly, a large area of optically active film may be cut into small area pieces via a laser of sharp roller cutter or other methods known in the art. In the embodiment illustrated in FIG. 14B, optically active film 730 is disposed on emitting surface 704 coated with optical adhesive 730 via a high precision pick and place tool 740. In some embodiments, pick and place tool 740 comprises a suction nozzle configured to pick up optically active film 730 and place optically active film 730 on emitting surface 704. Optical adhesive 730 secures optically active film 730 on emitting surface 704. In some embodiments, optically active film 730 is cured using hot air, UV light, and/or any other method known in the art. Optically active film 730 enables light emitting element 702 to operate at a desired color point (e.g., white light).

FIG. 15 is a dip coating system 900 in accordance with an embodiment of the present disclosure. Similar to the high precision pick and place system 700, dip coating system 900, uses a high precision pick and place tool 940. However, dip coating system 900 uses pick and place tool 940 to pick up each light emitting elements 902 and dip each light emitting element 902 into an ink composition 950. In some embodiments, pick and place tool 940 comprises a suction nozzle configured to pick up light emitting element 902 and dip a light emitting surface of light emitting element 902 into ink composition bath 950. The dipping time, surface wettability, and bath temperature will define the volume transfer. Ink composition 950 may comprise phosphor materials. In some embodiments, ink composition 950 comprises a PFS phosphor and/or a KFS phosphor. Additionally, or alternatively, ink composition 950 comprises an optical adhesive. Ink composition 950 may comprise any of the ink compositions described herein.

After a targeted dipping time, pick and place tool 940 removes light emitting element 902 from ink composition bath 950. The resulting coating 906 on light emitting element 902 is then cured. In some embodiments coating 906 is cured using hot air and/or UV light. Additionally, or alternatively, the ink composition may be cured using any known methods in the art. This process is repeated (e.g., light emitting element 902 is dipped into ink composition bath 950 and resulting coating 906 is cured) until a desired conversion layer is achieved. The cured coating on light emitting element 902 enables light emitting element 902 to operate at a desired color point (e.g., white light). More particularly, a LED (e.g., mini-LED, micro-LED, etc.), may be customized with a desired color point as a part which may be assembled to any desired panel in an electronic assembly line, resulting in a relatively quick, efficient, and cost-effective process.

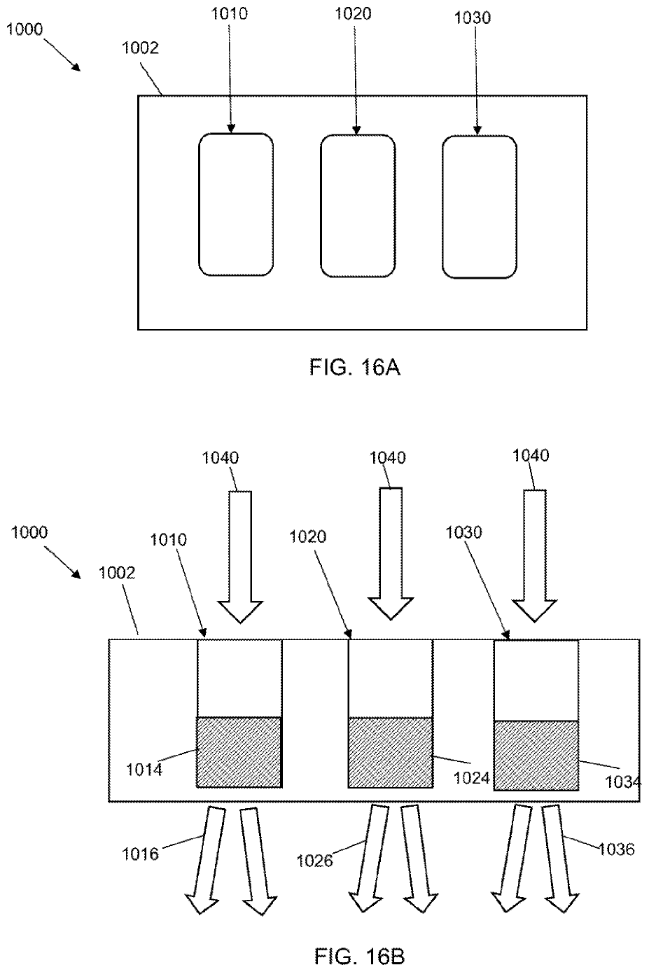

FIG. 16A is a top view of an example red-green-blue (RGB) pixel 1000 comprising a blue subpixel 1010, a green subpixel 1020, and a red subpixel 1030. FIG. 16B is a side view of an example RGB pixel layout 1000. Each subpixel may comprise a well comprising a plurality of walls. An ink composition including blue-emitting phosphors may be deposited in blue subpixel 1010, an ink composition including green-emitting phosphors may be deposited in green subpixel 1022, and an ink composition including red-emitting phosphors may be deposited in red subpixel 1030. The ink compositions deposited into blue subpixel 1012, green subpixel 1020, and red subpixel 1030 may cure into a color filter parts 1012, 1022, and 1032, respectively. As such, blue subpixel 1010 is configured to emit blue light 1016, green subpixel 1020 is configured to emit green light 1026, and red subpixel 1030 is configured to emit red light 1036. In some embodiments, each subpixel, 1010, 1020, 1030 comprises a color filter material 1014, 1024, 1034, respectively. In some embodiments, stencil printing is used to deposit the ink compositions. The stencil printing may be performed via contact stencil printing system 100 (see FIG. 6) or snap-off stencil printing system 200 (see FIG. 7). The ink composition may be cured using hot air, UV light, and/or any other method known in the art.

In some embodiments, an ink composition may comprise a refractive index of about 0.1 to about 3. In further embodiments, the ink composition may comprise a refractive index of about 1 to about 1.6. In further embodiments, the ink composition may comprise a refractive index of about 1.50. In further embodiments, the ink composition may comprise a refractive index of about 1.51. The ink composition comprising a relatively high refractive index, increases the effective path length of excitation light 1040 (e.g., the blue light) for additional absorption.

In some embodiments, a scattering agent is added to a subpixel, as noted above. In some embodiments, the scattering agent may comprise a refractive index of about 0.1 to about 3. In further embodiments, the scattering agent may comprise a refractive index of about 1 to about 1.6. In further embodiments, the scattering agent may comprise a refractive index of about 1.50. In further embodiments, the scattering agent may comprise a refractive index of about 1.51. The scattering agent comprising a relatively high refractive index, increases the effective path length of excitation light 1040 (e.g., the blue light) for additional absorption.

In some embodiments, a subpixel may be filled in part by a first ink composition, and in part by a second ink composition. The second ink composition may be located proximate to a portion of the pixel or subpixel through which excitation light enters (e.g., side 1002 in FIG. 16B). Excitation light 1040 may enter the pixel, and encounter the second ink composition and then subsequently, the first ink composition. The subpixel may be filled using a two-pass printing approach. The printing may be performed via contact stencil printing system 100 (see FIG. 6) or snap-off stencil printing system 200 (see FIG. 7). The ink composition may be cured using hot air, UV light, and/or any other method known in the art. The first ink composition and the second ink composition may comprise different refractive indexes. For example, in some embodiments, the second ink composition comprises a relatively low refractive index and the first ink composition comprising a relatively high refractive index. For example, in some embodiments, the first ink composition comprises a higher refractive index than the second ink composition. This causes excitation light to first encounter the second ink composition resulting in low reflection and then encounter the first ink composition, which increases the effective excitation light path once coupled into the color filter part. In further embodiments, the second ink composition comprises a refractive index of about 0.1 to about 2. In further embodiments, the second ink composition comprises a refractive index of about 0.1 to about 1.6. In further embodiments, the second ink composition comprises a refractive index of about 0.1 to about 1.51. In some embodiments, the first ink composition comprises a refractive index of greater than about 1. In further embodiments, the first ink composition comprises a refractive index of greater than about 1.3. In further embodiments, the first ink composition comprises a refractive index of greater than about greater than 1.50. In further embodiments, the first ink composition comprises a refractive index of greater than about 1.51.

In some embodiments, a subpixel may comprise a third ink composition, in addition to the first ink composition and the second ink composition. In such embodiments, the second ink composition may have a relatively low refractive index, the first ink composition may have a relatively high refractive index, and the third ink composition may have a relatively high refractive index. In such embodiments, each of the first ink composition and the third ink composition may have a higher refractive index than the second ink composition. In further embodiments, the second ink composition comprises a refractive index of about 0.1 to about 2. In further embodiments, the second ink composition comprises a refractive index of about 0.1 to about 1.6. In further embodiments, the second ink composition comprises a refractive index of about 0.1 to about 1.51. In some embodiments, the first ink composition comprises a refractive index of greater than about 1. In further embodiments, the first ink composition comprises a refractive index of greater than about 1.3. In further embodiments, the first ink composition comprises a refractive index of greater than about greater than 1.50. In further embodiments, the first ink composition comprises a refractive index of greater than about 1.51. In some embodiments, the third ink composition comprises a refractive index of greater than about 1. In further embodiments, the third ink composition comprises a refractive index of greater than about 1.3. In further embodiments, the third ink composition comprises a refractive index of greater than about greater than 1.50. In further embodiments, the third ink composition comprises a refractive index of greater than about 1.51.

In some embodiments, at least one film (not shown) is disposed over side of one or more subpixels 1010, 1020, 1030 or over pixel 1000 through which excitation light enters (e.g., side 1002). The at least one film may be configured to change the optical properties. For example, the at least one filter may comprise a film which transmits blue light and reflects red and/or greed light, thereby increasing brightness by increasing the amount of blue light entering subpixels 1010, 1020, and 1030 and passing through blue subpixel 1010 and being converted to green light through green subpixel 1020 and red light through red subpixel 1030. In some embodiments, the at least one filter comprises a dichroic color filter. Additionally, or alternatively, the at least one film is configured to protect the ink composition from at least one of oxygen or moisture.

In some embodiments, quantum dots in a color filter (QDCF) are utilized. QDCF may improve the color quality, viewing angle and energy efficiency of displays. By using a blue light source such as OLED, LED, mini-LED, or micro-LED, or a UV light source, and replacing traditional color filters with a QDCF material, at least a portion of the blue light gets converted to a higher wavelength range such as red and/or green light.

In some embodiments, RGB pixel 1000 is part of a display device comprising with a backlight unit (BLU) configured to emit a blue light 1040. In such embodiments, QDCF may comprise scattering agent in blue subpixel 1010 and a quantum dot in the red subpixel 1030 and green subpixel 1020 to attain wide color gamut. In addition to the quantum dots in the red subpixel 1030 and green subpixel 1020, at least one binder, at least one scattering agent and/or an additional color filter material that absorbs blue light may be added to minimize blue light leakage through the subpixel, which would result in lower color gamut.

The nanometer size of the quantum dots, the high absorption cross section, and the surface termination of the quantum dots with ligands has resulted in the commercialization of QDCF containing display architectures. However, using a QDCF has some draw backs, such as self-absorption losses. Further, encapsulation of the quantum dots is typically required in QDCF containing displays to prevent the degradation of the quantum dots due moisture and/or oxygen. The encapsulation may introduce parallax issues. Additionally, the necessary coatings, shells, printing, and/or curing processing may decrease the quantum efficiency of the quantum dots in the QDCF part. In some cases, the net effect is a decrease in external quantum efficiency due to significant overlap between the quantum dot absorption and emission in heavily loaded inks. It was previously believed that typical phosphors could not be used in color filter applications as the particle size is too large, and, if synthesized to be submicron, the quantum efficiency and absorption would be too low and agglomeration too high to print into a subpixel. The embodiments disclosed herein address these foregoing issues with current QDCF.

In some embodiments in accordance with the present disclosure, stencil printing is used to fill red subpixel 1030 with an ink composition. In some embodiments, the ink composition comprises a KSF phosphor (K₂SiF₆:Mn) with small particle size and high manganese content. As opposed to quantum dot color filter solutions, KSF phosphor (K₂SiF₆:Mn) has a narrower emission intensity, does not have self-absorption issues in thick films, and does not decrease in quantum efficiency when cured into a color filter part. In further embodiments, the KSF phosphor has a D50 particle size from about 0.1 μm to about 15 μm and comprises a Mn content of at least 2.0 wt %. In further embodiments, the KSF phosphor has a D50 particle size from about 0.1 μm to about 8 μm and comprises a Mn content of at least 2.0 wt %. In further embodiments, the KSF phosphor has a D50 particle size from about 0.1 m to about 4 μm and comprises a Mn content of 2.0-4.0 wt %. In other embodiments, the ink composition includes an NSF phosphor (Na₂SiF₆) with small particle size and high manganese content. The stencil printing may be performed via contact stencil printing system 100 (see FIG. 6) or snap-off stencil printing system 200 (see FIG. 7). The ink composition may be cured using hot air, UV light, and/or any other method known in the art.

In some embodiments, stencil printing is used to coat red subpixel 1030 with an ink composition comprising a KSF phosphor, as described above. The ink composition may further comprise a surface agent such as MgF₂ to allow for a well dispersed KSF ink with good printability that absorbs the majority of the excitation light (e.g., blue light or UV light) and has a quantum efficiency of greater than 80%. Such ink compositions lack self-absorption, have good reliability, and do not require encapsulation. Further, typical KSF inks require 30-70% loading to absorb the majority of excitation light in a well having a depth of 8-16 μm. In further embodiments, green subpixel 1020 is coated with a green luminescent material and a scattering agent or a blue luminescent material is added to blue subpixel 1010. Such embodiments enable a functioning display when excited by blue LED or OLED light or UV light.

Additionally, in some embodiments, one or more walls of a subpixel are coated with a reflective (e.g., white) surface. For example, in some embodiments, one or more walls of red subpixel 1030 is coated with a reflective (e.g., white).

In some embodiments, subpixels of RGB pixel 1000 comprise a depth of 6-20 μm. In further embodiments, subpixels of RGB pixel 1000 comprise a depth of 14-20 μm. The inventors found that increasing the well depth from 8 μm to 16 μm, red light emission by 1036 by red subpixel 1030 increased by over 30% compared to a red subpixel comprising a well depth of 8 μm.

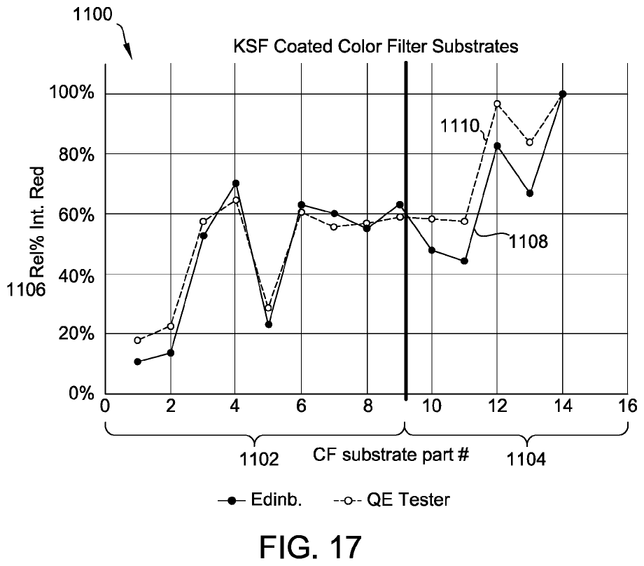

FIG. 17 is a graph 1100 comparing red light emission by color filter parts with KSF phosphor filled red subpixel comprising a depth of 8 μm versus a depth of 16 μm. In FIG. 17, the ink refractive index and viscosity varied among the color filter parts, which is described in more detail below. In FIG. 17, parts 1-9 of x-axis 1102 correspond to a well depth of 8 μm versus and parts 10-14 of x-axis 1104 correspond to a well depth of 16 μm.

The red-light emission was tested using a first method 1108 using an Edinburgh spectrometer and a second method 1110 using a QE tester. In first method 1108, the coated color filter part was excited from a Xe lamp with 450 nm excitation selected via a monochromator. A series of gratings and mirrors result in about a 2 cm spot size exciting the 60×60 mm coated color filter part. Most of the blue light hitting the red subpixel transmits into the cured subpixel and attenuates as KSF phosphor ink absorbs the light such that less than 20% of the incident blue light needs to be absorbed by the color filter material after passing through the cured KSF phosphor ink. KSF phosphor ink converts the absorbed blue photons into red photons via down conversion, and the emitted red photons pass through the color filter material and out the back side of the color filter part. These emitted red photons then pass through a second monochromator and are detected by a photomultiplier tube (PMT) detector. KSF phosphor printed color parts were then compared to one another based on the integrated red emission intensity.

Second method 1110 utilized a QE tester, which involved a blue LED with a reflective ring. The KSF phosphor coated color filter parts sit on top of the ring in a closed integrating sphere, and the emitted red intensity is coupled out of the integrating sphere through a fiber coupled to a charge-coupled device (CCD) array detector. The integrated red emission intensity of each part can then be compared and normalized to the part having the highest integrated emission intensity. The correlation between first method 1108 and second method 1110 was 95.6%, thereby providing confidence to the measurements.

Color Filter Part 14 of FIG. 17 was printed from an ink composition with a refractive index of greater than 1.57 and a viscosity of about 5000 cPs. The well of Color Filter Part 14 was determined to be completely filled via profilometry. As clearly illustrated in FIG. 17, Part 14 resulted in the greatest brightness. 3-5 micron NSF phosphor printed Color Filter parts were also fabricated and measured and achieved up to 90% brightness relative to Color Filter Part 14.

### EXAMPLES

### Example 1

### Sample OS042022:

In a 15 ml (4 dram) amber vial weigh 2.2167 g SFZ-1+0.4545 g BB PTh+0.8589 g DGME. The mixture was shaken on a vortex mixer for 15-20 s. The first increment of PFS (1.0007 g) was added and the mixture was shaken on the vortex mixer for 20-30 s. The second portion of PFS (1.0008 g) was added and the mixture was again shaken on the vortex mixer followed by 3-5 min bath sonication. The third amount of PFS (1.0065 g) was added followed by vortex mixing and bath sonication. After the last addition of PFS (0.9956 g) and subsequent mixing and sonication, the slurry was too dry and 1.1579 g DGME were added, again followed by mixing and bath sonication. The slurry was still thick and another 0.2476 g DGME were added followed by vortex mixing and bath sonication. Then the slurry was pulse sonicated (1 s on, 2 s off) with a horn sonicator for a total 20 s active sonication. The slurry became warm, but was still thick. Additional 0.1102 g DGME were added, again followed by vortex mixing and bath sonication. The slurry was again pulse sonicated (1 s on, 2 s off) with a horn sonicator for a total 20 s active sonication. The slurry was then rolled over-night and the next day was pulse sonicated (1 s on, 2 s off) with a horn sonicator for a total 20 s active sonication. Then it was placed in a desiccator under vacuum for 15 min to degas before coating.

### Doctor Blade Coating on Glass Substrates

The ink was coated on 1″×1″ Corning glass substrates of 1.1 mm thickness using an Erichsen Coatmaster 510 coater with a vacuum stage. To obtain final film thicknesses of 10-30 μm, applicators with 1-3 mil gap were used at a speed of 10 mm/s.

The glass substrates coated with the wet films were placed on a hotplate at 11° C. to remove the solvent and then they were UV cured for 2 min.

TABLE 1

| Film ID | Gap (mil) | Final thickness (um) |
|---|---|---|
| OS042022-1 mil-A | 1 | 7 |
| OS042022-1 mil-B | 1 | 8 |
| OS042022-1 mil-C | 1 | 11 |
| OS042022-1 mil-D | 1 | 12 |
| OS042022-1 mil-E | 1 | 14 |
| OS042022-1 mil-F | 1 | 15 |
| OS042022-2 mil-A | 2 | 18 |
| OS042022-2 mil-B | 2 | 20 |
| OS042022-2 mil-C | 2 | 22 |
| OS042022-2 mil-D | 2 | 22 |
| OS042022-3 mil-A | 3 | 28 |
| OS042022-3 mil-B | 3 | 28 |
| OS042022-3 mil-C | 3 | 32 |
| OS042022-3 mil-D | 3 | 32 |

### Sample OS041522:

In a 15 ml (4 dram) amber vial weigh 2.218 g SFZ-1+0.4562 g BB PTh+0.5515 g DGME. The mixture was shaken on a vortex mixer for 15-20 s. The first increment of PFS (1.0004 g) was added and the mixture was shaken on the vortex mixer for 20-30 s. The second portion of PFS (1.0072 g) was added and the mixture was again shaken on the vortex mixer followed by 3-5 min bath sonication. The third amount of PFS (1.0122 g) was added followed by vortex mixing and 3-5 min bath sonication. After the last addition of PFS (0.9768 g) and subsequent mixing and 3-5 min bath sonication, the slurry was too thick and 0.2562 g DGME were added, again followed by mixing and bath sonication. The slurry was still thick and another 0.2097 g DGME were added followed by vortex mixing and 3-5 min bath sonication. Then the slurry was pulse sonicated (1 s on, 2 s off) with a horn sonicator for a total 1 min active sonication. The slurry became warm and thinned out. The slurry was then rolled over-night and the next day was pulse sonicated (1 s on, 2 s off) with a horn sonicator for a total of 1 min active sonication and became warm. Then it was placed in a desiccator under vacuum for 15 min to degas before coating.

### Doctor Blade Coating on Glass Substrates

The ink was coated on 1″×1″ Corning glass substrates of 1.1 mm thickness using an Erichsen Coatmaster 510 coater with a vacuum stage. To obtain final film thicknesses of 10-30 μm, applicators with 1-3 mil gap were used at a speed of 10 mm/s.

The glass substrates coated with the wet films were placed on a hotplate at 110 C to remove the solvent and then they were UV cured for 2 min.

TABLE 2

| Film ID | Gap (mil) | Film thickness (μm) |
|---|---|---|
| OS041522-0.5 mil-A | 0.5 | 3 |
| OS041522-0.5 mil-B | 0.5 | 7 |
| OS041522-0.5 mil-C | 0.5 | 5 |
| OS041522-1 mil-A | 1 | 9 |
| OS041522-1 mil-B | 1 | 13 |
| OS041522-1 mil-C | 1 | 12 |
| OS041522-1 mil-D | 1 | 15 |
| OS041522-1 mil-E | 1 | 14 |
| OS041522-1.5 mil-A | 1.5 | 18 |
| OS041522-1.5 mil-B | 1.5 | 22 |
| OS041522-1.5 mil-C | 1.5 | 14 |
| OS041522-1.5 mil-D | 1.5 | 16 |

### Sample OS031422:

In a 15 ml (4 dram) amber vial weigh 3.6793 g SFZ-1+0.602 g BB PTh+1.0089 g DGME. The mixture was shaken on a vortex mixer for 15-20 s. 6.3621 g of PFS (total amount) was added in three portions. After each portion was added the mixture was shaken on the vortex mixer for 20-30 s followed by 3-5 min bath sonication. Then the slurry was pulse sonicated for 3 min (1 s on, 2 s off) with a horn sonicator for a total 1 min active sonication. Then it was placed in a desiccator under vacuum for 10 min to degas before coating.

### Doctor Blade Coating on Glass Substrates

The ink was coated on 1″×1″ Corning glass substrates of 1.1 mm thickness using an Erichsen Coatmaster 510 coater with a vacuum stage. To obtain final film thicknesses of 10-30 μm, applicators with 1-3 mil gap were used at a speed of 10 mm/s.

The glass substrates coated with the wet films were placed on a hotplate at 11° C. to remove the solvent and then they were UV cured for 2 min.

TABLE 3

| | | Film | | | |
|---|---|---|---|---|---|
| | Gap | Thick | Blue | Conv eff | Red Conv |
| Film ID | (mil) | (μm) | Abs | (Power) (%) | Ratio (%) |
| OS031422-0.5 mil-A | 0.5 | 24 | 52.1 | 55.5 | 28.9 |
| OS031422-0.5 mil-B | 0.5 | 22 | 55 | 56.4 | 31 |
| OS031422-1 mil-A | 1 | 25 | 60 | 54.8 | 32.9 |
| OS031422-1 mil-B | 1 | 31 | 66 | 55.1 | 36.4 |
| OS031422-1 mil-C | 1 | 32 | 63.2 | 59.6 | 37.6 |
| OS031422-1 mil-D | 1 | 33 | 66 | 55.6 | 36.7 |
| OS031422-2 mil-A | 2 | 44 | 73.2 | 54.9 | 40.1 |
| OS031422-2 mil-B | 2 | 43 | 75.4 | 54.1 | 40.8 |
| OS031422-2 mil-C | 2 | 44 | 76 | 54.9 | 40.1 |
| OS031422-3 mil-A | 3 | 54 | 80.8 | 54.6 | 44.1 |
| OS031422-3 mil-B | 3 | 57 | 82 | 53.4 | 43.8 |
| OS031422-3 mil-C | 3 | 57 | 82.2 | 55.9 | 45.9 |
| OS031422-3 mil-D | 3 | 58 | 83.3 | 53.7 | 44.7 |

### Sample OS031122:

In a 15 ml (4 dram) amber vial weigh 4.2766 g SFZ-1+0.2354 g BB PTh+1.0381 g DGME. The mixture was shaken on a vortex mixer for 15-20 s. The first increment of PFS (2.7311 g) was added and the mixture was shaken on the vortex mixer for 20-30 s. The second portion of PFS (2.3979 g) was added and the mixture was again shaken on the vortex mixer. The slurry was too dry. 1.066 g DGME was added and the mixture was shaken on the vortex mixer for 20-30 s. The third amount of PFS (2.2586 g) was added followed by vortex mixing. The slurry was too thick and 0.4086 g DGME were added, again followed by mixing. The slurry was still thick and another 0.2176 g DGME were added followed by vortex mixing. Then the slurry was pulse sonicated for 3 min (1 s on, 2 s off) with a horn sonicator. The slurry was too thin. 0.4131 g PFS was added followed by vortex mixing. The slurry was pulse sonicated for 3 min (1 s on, 2 s off) with a horn sonicator and 3-5 min bath sonication. Then it was placed in a desiccator under vacuum for 15 min to degas before coating.

### Doctor Blade Coating on Glass Substrates

The ink was coated on 1″×1″ Corning glass substrates of 1.1 mm thickness using an Erichsen Coatmaster 510 coater with a vacuum stage. To obtain final film thicknesses of 10-30 μm, applicators with 1-3 mil gap were used at a speed of 10 mm/s.

The glass substrates coated with the wet films were placed on a hotplate at 110 C to remove the solvent and then they were UV cured for 2 min.

TABLE 4

| | Thick | Blue | Conversion eff | Red Conv |
|---|---|---|---|---|
| Film ID | (μm) | Abs (%) | (Power) (%) | Ratio (%) |
| OS031422-0.5 mil-A | 24 | 52.1 | 55.5 | 28.9 |
| OS031422-0.5 mil-B | 22 | 55 | 56.4 | 31 |
| OS031422-1 mil-A | 25 | 60 | 54.8 | 32.9 |
| OS031422-1 mil-B | 31 | 66 | 55.1 | 36.4 |
| OS031422-1 mil-C | 32 | 63.2 | 59.6 | 37.6 |
| OS031422-1 mil-D | 33 | 66 | 55.1 | 36.4 |
| OS031422-2 mil-A | 44 | 73.2 | 54.9 | 40.1 |
| OS031422-2 mil-B | 43 | 75.4 | 54.1 | 40.8 |
| OS031422-2 mil-C | 44 | 76 | 54.9 | 41.7 |
| OS031422-3 mil-A | 54 | 80.8 | 54.6 | 44.1 |
| OS031422-3 mil-B | 57 | 82 | 53.4 | 43.8 |
| OS031422-3 mil-C | 57 | 82.2 | 55.9 | 45.9 |
| OS031422-3 mil-D | 58 | 83.3 | 53.7 | 44.7 |

### Sample OS031022:

In a 15 ml (4 dram) amber vial weigh 6.1161 g SFZ-1+3.0002 g PFS. The mixture was shaken on a vortex mixer for 15-20 s and 3-5 min bath sonication. A portion of PFS (3.0064 g) was added and the mixture was shaken on the vortex mixer for 20-30 s. The mixture was too dry. 0.5112 g DGME was added and the mixture was shaken on the vortex mixer for 20-30 s. The third amount of PFS (3.0051 g) was added followed by vortex mixing. The mixture was too dry and 0.5141 g DGME were added, again followed by mixing. Then the slurry was pulse sonicated (1 s on, 2 s off) with a horn sonicator for 1 min active sonication. The slurry was too thin. 1.0013 g PFS was added followed by vortex mixing and the slurry was still too thin. 0.5086 g PFS was added followed by vortex mixing and 3-5 min bath sonication. The slurry was pulse sonicated (1 s on, 2 s off) with a horn sonicator for 1 min active sonication. Then it was placed in a desiccator under vacuum for 15 min to degas before coating.

### Doctor Blade Coating on Glass Substrates

The ink was coated on 1″×1″ Corning glass substrates of 1.1 mm thickness using an Erichsen Coatmaster 510 coater with a vacuum stage. To obtain final film thicknesses of 10-30 μm, applicators with 1-3 mil gap were used at a speed of 10 mm/s.

The glass substrates coated with the wet films were placed on a hotplate at 110 C to remove the solvent and then they were UV cured for 2 min.

TABLE 5

| | Thick | Blue | Conv eff | Red Conv |
|---|---|---|---|---|
| Film ID | (μm) | Abs (%) | (Power) (%) | Ratio (%) |
| OS031022-1 mil-A | 44 | 75.6 | 51.5 | 38.9 |
| OS031022-1 mil-B | 41 | 70.8 | 53.1 | 37.6 |
| OS031022-1 mil-C | 44 | 72.8 | 51.7 | 37.6 |
| OS031022-2 mil-A | 51 | 79 | 52.4 | 41.4 |
| OS031022-2 mil-B | 50 | 78.5 | 51.5 | 40.5 |
| OS031022-2 mil-C | 37 | 72.3 | 53.3 | 38.6 |
| OS031022-3 mil-A | 70 | 88.8 | 49.3 | 43.8 |
| OS031022-3 mil-B | 65 | 86 | 50.2 | 43.2 |
| OS031022-3 mil-C | 85 | 90.2 | 48.9 | 44.1 |
| OS031022-4 mil-A | 88 | 89.9 | 50.4 | 45.3 |
| OS031022-4 mil-B | 71 | 86.4 | 52.8 | 45.6 |
| OS031022-4 mil-C | 91 | 90 | 49.7 | 44.7 |

### Example 2

The table below describes examples of inks containing small-size, surface-modified phosphor material developed in this invention. Ink embodiments listed in this table illustrate the versatility of the present technology in producing fluids with tailored viscosity and using solvents with demonstrated printability. Moreover, it is exemplified how resin systems obtained off-the-shelf from different commercial vendors can be employed leading to stable phosphor dispersions.

### Experimental Procedure to Formulate Inks in Samples 1-4:

Add resin to a glass vial using a disposable pipette. Add solvent to the resin and vortex for 3 minutes or until resin is completely dissolved in solvent. In some embodiments, the solvent is optional. Visually inspect the bottom of the jar in corners where resin could be difficult to agitate. Add YAG in ˜2 g increments, vortex mixing the solution for 1 minute in between each powder addition. Add PFS in ˜1-2 g increments, vortex mixing the solution for 1 minute in between each powder addition. Sonicate the solution with probe sonicator at 25% power for 1 minute in pulse mode (total run time ˜3 minutes) for is ON, 2s OFF. Remove the excess solvent in a roto-evaporator under vacuum equivalent to 75 Torr with a speed between 100 and 170 RPM and bath temperature of 45° C. Take ink mass measurements in regular interval of times (for instance, every hour) and stop when target viscosity is achieved.

Resin free, low viscosity ink. Sample ink 6 in the table above is composed of a co-solvent mixture of triethylene glycol monomethyl ether (TGME) and diethylene glycol dimethyl ether (DGDE) at a 1:1 by mass ratio. Ethyl cellulose (EC-HH, 300 Pa-s viscosity) was used as the binder material. Ethyl cellulose was added to the TGME/DGDE co-solvent blend at 1 wt % and mixed with a stir bar until all binder was dissolved. Then, PFS was added equivalent to 8 wt % of the co-solvent/binder blend. The suspension was stirred at RT to mix and then vortexed for 2 minutes. Following vortex mixing, the suspension was bath sonicated for 10 min to 1 h to decrease the average agglomerate size. Following sonication, the suspension was rolled on a ball mill at 60 rpm for 2 h. Then the solution was transferred to an amber glass vial and stirred for 2 h at 60° C.

TABLE 6

| | Resin | | Solvent | | | | |
|---|---|---|---|---|---|---|---|
| | | Amount | | Amount | Phosphor | | Viscosity |
| Ink | Type | (g) | Type | (g) | (g) | Additives | (cP) |
| 1 | NOA170 | 10.531 | Acetone | 1.552 | 10.075 | — | 6,100 |
| 2 | NOA170 | 10.065 | DMF | 1.029 | 2.671 | — | 718 |
| 3 | NOA68T | 12.427 | DMF | 1.281 | 4.028 | — | 3,350 |
| 4 | NOA68T | 5.525 | Acetone | 1.793 | 0.880 | YAG, ZrO₂ | 16,545 |
| 5 | SR454 | 12.070 | — | — | 4.280 | — | 118 |
| 6 | — | — | TGME/DGDE | 4.600 | 0.400 | EC-HH | 15 |

Ink composition using high viscosity resin, solvent and additives. Ink 4 in the table is an exemplary formulation where NOA68T was used. This embodiment may contain different types of high viscosity resins that can be photo- or thermally cured and may have starting viscosities ranging from 10,000 cP to 30,000 cP (centipoise). The amount of solvent added to the ink may vary from 0% to 50% of the weight of the base resin. The type of solvent can be any of the ones mentioned above. In exemplary inks 3 and 4, Dimethylformamide (DMF) and Acetone were used, respectively. The ink must contain between 5% and 60% of PFS phosphor material. Phosphor particle size (d50) can be within a 0.5-10 micrometer range. Additives like scattering agents (for instance, ZrO₂) and auxiliary phosphor emitters like YAG phosphor can be used in quantities that vary from 1% to 60%.

Ink composition using medium viscosity resin, solvent and additives. Inks 1 and 2 in the table are exemplary formulations where NOA170 resin was used. This embodiment may contain different types of medium viscosity resins that can be photo- or thermally cured and may have starting viscosities ranging from 1,000 cP to 10,000 cP. The amount of solvent added to the ink may vary from 0% to 50% of the weight of the base resin. The type of solvent can be any of the ones mentioned above. In exemplary inks 1 and 2, Acetone and DMF were used, respectively. The ink must contain between 5% and 60% of PFS phosphor material. Phosphor particle size (d50) can be within a 0.5-10 micrometer range. Although exemplary inks 1 and 2 do not contain such molecules, additives like scattering agents (for instance, ZrO₂) and auxiliary phosphor emitters like YAG phosphor can also be used in this composition in quantities that vary from 1% to 60%.

Ink composition using low viscosity resin, solvent and additives. Ink 5 in table above is an example of low viscosity formulation where SR454 resin was used. This embodiment may contain different types of low viscosity resins that can be photo- or thermally cured and may have starting viscosities ranging from 10 cP to 1,000 cP. The amount of solvent added to the ink may vary from 0 to 10% of the weight of the base resin. The type of solvent can be any of the ones mentioned above. In exemplary ink 5, no solvent was used. The ink must contain between 5% and 60% of PFS phosphor material. Phosphor particle size (d50) can vary between 0.5 and 5 micrometers. Although exemplary ink 5 do not contain additives, the same can be present in quantities that vary from 1% to 60%.

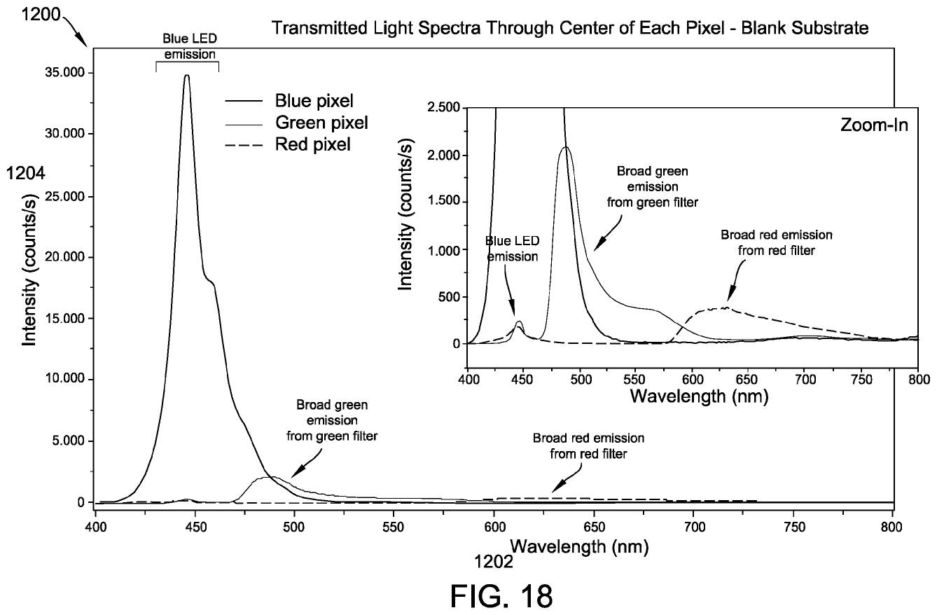

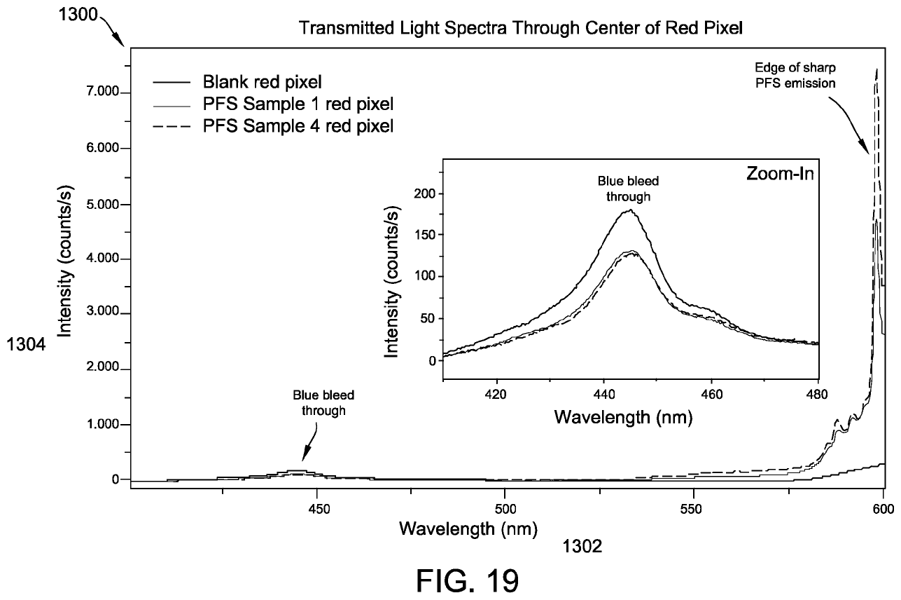

FIG. 18 illustrates a graph 1200 showing photoluminescence mapping of a blank substrate comprising a blue subpixel, a green subpixel, and a red subpixel. More particularly, graph 1200 shows intensity (counts/s) 1204 as a function of wavelength (nm) 1202 of a blank substrate. As shown in graph 1200, a broad red-light emission from the red subpixel and a broad green light emission from the green subpixel was observed. FIG. 19 illustrates a graph 1300 shows intensity (counts/s) 1304 as a function of wavelength (nm) 1302 of a KSF filled red subpixel. As shown in graph 1300, a strong red emission was observed for KSF red subpixel at wavelengths above 580 nm, thereby demonstrating increased light intensity of the KSF filled red subpixel as compared with the blank substrate of FIG. 18.

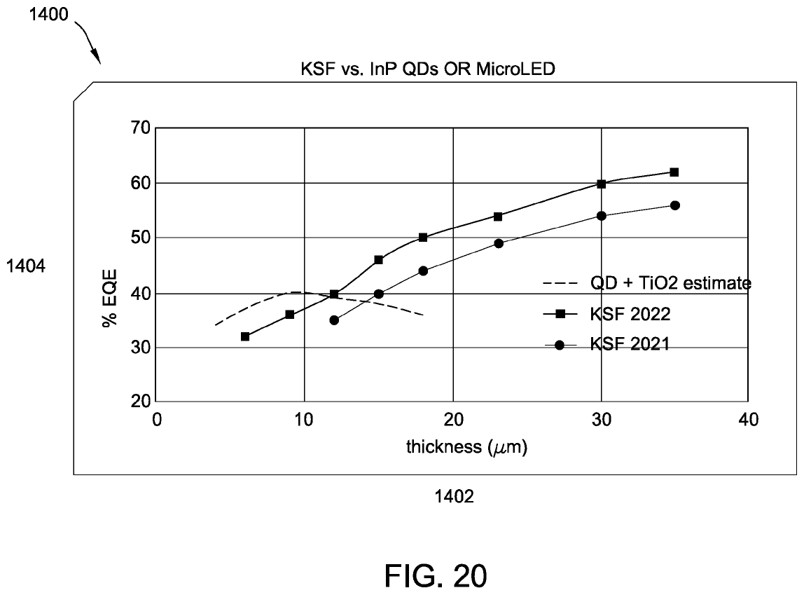

FIG. 20 illustrates a graph 1400 of percent external quantum efficiency (EQE) 1404 versus thickness measurements (μm) 1402 in relevant form factors to understand product performance. EQE 1404 is proportional to the amount of light absorption at 450 nm (LED or OLED) and the internal quantum efficiency. Although a high EQE for the thinnest possible film is desirable, as higher thicknesses are associated with higher self-absorption losses. However, in general, for luminescent materials, the thinner the film, the lower the EQE. However, the ink formulations and systems and methods for dispensing and printing such ink formulations as described herein led to a 10 to 20 percent EQE improvement, enabling thinner films to be used.

A see-through display or transparent display is an electronic display that allows the user to see what is shown on the screen while still being able to see through it. The main applications of a transparent display are head-up displays, augmented reality systems, digital signage, and general large-scale spatial light modulation. Transparent displays deliver many of the benefits of digital signage while allowing viewers to see the scene behind the display by mounting light-emitting devices directly on a transparent glass to serve as pixels. These see-through installations may eliminate the need for a backlight or enclosure and are often used in applications including retail merchandising, corporate displays, museum exhibits, award/trophy cases, and heads up displays including automotive applications. The light source for transparent displays may comprise LEDs, OLEDs, mini-EDS, and/or micro-LEDs. In general, arrays of smaller size LEDs such as mini-LEDs or micro-LEDs allow for higher transparency and higher resolution than larger size LEDs, and have the potential to be brighter than OLED-based transparent displays. However, in general, as the size of the micro-led decreases, the EQE of the micro-LEDs may also decrease. Typical display substrates comprises a plurality of separate micro-LEDs, OLEDs, mini-EDS, and/or micro-LEDs arranged in a pixel group wherein the pixel group includes a blue-emitting device, a green-emitting device, and a red-emitting device. In embodiments in accordance with the present disclosure, the pixel group may comprise a plurality of blue-emitting or UV-emitting each LEDs, OLEDs, mini-LEDs, and/or micro-LEDs and utilize color conversion techniques to create the other colors of the display. In many transparent display applications, it is desirable to maximize transparency by using small size LEDs, thin metallization lines, as well as transparent conducting materials (such as indium tin oxide) instead of metallization lines.

In some embodiments, a metallization layer may include an electrode layer and optionally a barrier layer though other layers may be included. In some embodiments, metallization layer has a thickness of approximately 0.1-2 microns. An electrode layer may make ohmic contact to the GaN micro-LED, and may be formed of a high work-function metal such as Ni, Au, Ag, Pd and Pt. In some embodiments, the electrode layer may be reflective to light emission. In other embodiments, the electrode layer may be transparent to light emission. In some embodiments, the width of the laterally separated locations of metallization layer is less than or equal to the width of the bottom surface of the array of micro p-n diodes. The metallization layer is typically formed with uniform thickness and may be deposited by a variety of suitable methods such as sputtering, electron beam evaporation, or plated with a seed layer.

Using micro-LEDs with relatively larger reflecting surfaces and phosphor drops may produce a satisfactory light output with minimal loss in transparency. Transparent displays in accordance with the present disclosure may be at least 50% transparent, and in some cases, at least 60% transparent. In some embodiments, the ink composition may comprise a relatively high refractive index. In one embodiment, the ink composition comprises a KSF phosphor (K₂SiF₆:Mn⁴⁺) that is less than 5 micron in size and has a Mn content of at least 1.5 wt % Mn content. Such KSF phosphor may be mixed with a green- or yellow-emitting phosphor, such as (Y, Ga, Lu, Gd, Tb)₃Al₅O₁₂:Ce³⁺. The ink composition may comprise a refractive index of greater than about 1.49 to create scatter with KSF phosphor that has refractive index of about 1.4. This increases the effective path length of the blue pump source and in a bank micro-LED structure that has more transmission and reflection than absorption, and therefore will have increased red and green emission (lower CCT) and higher light output at a given phosphor loading. This architecture produces a phosphor converted micro-LED array with a color temperature above CCX>0.2, CCY>0.2. Typical inks contain at least 20% phosphor loading and potentially as high as 70% phosphor loading with the green phosphor to red phosphor loading ratio typically being at least about 2:1 by weight and up to about 20:1 by weight.

In some embodiments, a viscosity of the ink composition used may be about 100 cPs to about 30,000 cP. In further embodiments the viscosity of the ink composition may be 500 cPs to 20,000 cPs. In some embodiments, each of the micro-LEDs are located within a banked structure (e.g., bank structure 246 illustrated in FIG. 9) allows for lower viscosity inks down to perhaps 100 cPs. High quality, uniform printed parts were fabricated with inks from 500 cPs to 20,000 cPs. Bank structures using lower viscosity inks may produce more uniform phosphor converted micro-LED arrays post printing through a degassing step prior to curing.

In some embodiments, at least one reflective layer is formed around each LED, OLED, mini-LED, and/or micro-LED. The at least one reflective layer may enable a higher conversion rate, as it increases the probability of higher and/or multiple internal reflections of passing light which increases the travelled path of light in the conversion layer leading to higher conversion rate.

In some embodiments, the at least one reflective layer is formed from metals with high reflectivity in visible range, such as Al and Ag, and/or metals forming reflective or transparent oxides, such Al. In some embodiments, the at least one reflective layer comprises one or more dielectric mirrors and/or dichroic mirrors. The dielectric mirrors and/or dichroic mirrors may be tuned to reflect specific bands and may effectively reflect narrow-band emissions.

In some embodiments, the at least one reflective layer is deposited around each LED, OLED, mini-LED, and/or micro-LED via screen/stencil printing (e.g., using contact stencil printing system 100, snap-off stencil printing system 200, etc.), high-resolution masking techniques, or inkjet printing. In some embodiments, the at least one reflective layer is deposited before LED placement, possibly at the same step (and by same deposition techniques) as metallization lines of the LED array, thus avoiding additional steps and lowering the cost of the process. Additionally, or alternatively, a scattering agent, such as TiO₂ or ZrO₂, are added. In further embodiments, the scattering agent is about 0.1 μm to about 4 μm in particle size.

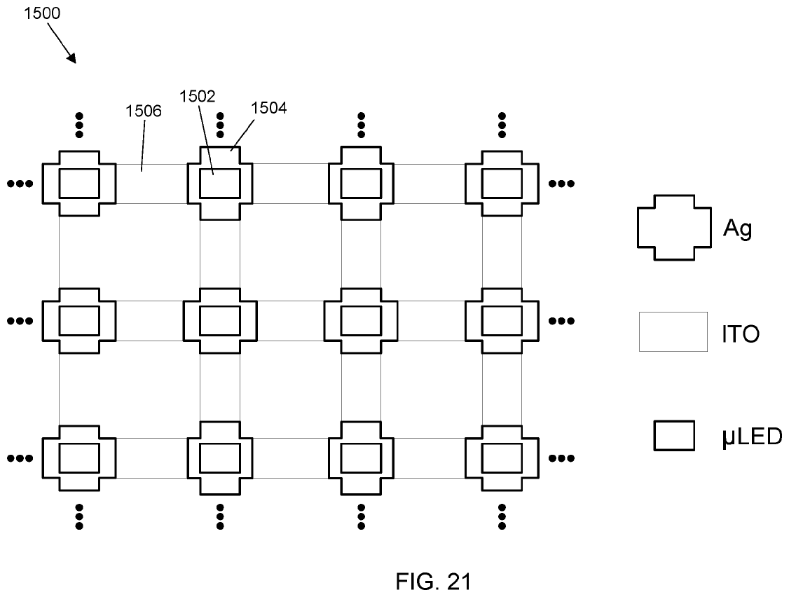

FIG. 21 is a schematic diagram of hybrid conductive grid 1500. Hybrid conductive grid 1500 may provide both higher reflectivity under and around micro-LEDs 1502 and higher transparency in regions between the micro-LEDs 1502. In some embodiments, hybrid conductive grid 1500 is produced by sputtering Indium Tin Oxide (ITO) 1506 and Ag conductive segments 1504 in an alternated fashion to form an interconnected conductive grid with the desired properties. Hybrid conductive grid 1500 may enhance the reflective properties of the at least one reflective layer discussed herein.

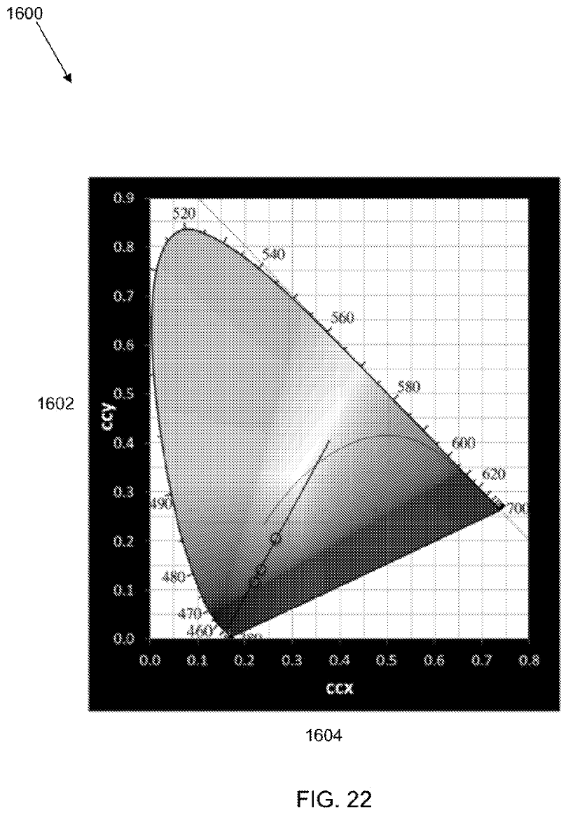

FIG. 22 is a contour plot of the color point of an example LED array comprising a dielectric mirror. To measure the color point of the phosphor deposit in LED arrays, a Konica Minolta CS-150 color and luminance meter was used. The color point is measured before the phosphor application (e.g., a bare LED) and after (e.g., a coated LED). To make the measurement, the color meter must be placed at some distance in front of light emitting surface. A typical color point of a bare blue-emitting LED, emitting around 450 nm peak, is measured CCX=0.1640, CCY=0.0130.

In the case of transparent substrate, some emitted light may escape through the substrate to the back of the device. This effect can be significant when the phosphor is deposited over transparent areas of the substrate. Measuring luminance and color point emitted from both sides of the device can help assess how much light is lost through the substrate, as illustrated in Table 7. More particularly, Table 7 demonstrates that about 30% of the light in the example LED array is emitted from the back of the device (column Back), and that its color point is shifted further away from the blue-emitting device (e.g., the bare LED), comparing to the light emitted from the front of an LED array which comprises deposited phosphor (column Front). By placing a mirror behind the device returns the luminance to the front and shifts the overall color point proportionally (column Reflected to Front). FIG. 22 is a contour plot using the data from Table 7.

TABLE 7

| | | | | Reflected to |
|---|---|---|---|---|
| | Bare LED | Front | Back | Front |
| Luminance, cd/m2 | n/a | 6888 | 3259 | 9715 |
| ccx | 0.1640 | 0.2190 | 0.2653 | 0.2334 |
| ccy | 0.0130 | 0.1172 | 0.0680 | 0.1427 |

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An ink composition comprising a phosphor material comprising a Mn⁴⁺ doped phosphor of formula 1 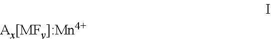
and at least one binder material or solvent, wherein the Mn⁴⁺ doped phosphor has a D50 particle size from about 0.5 microns to about 15 microns, and wherein the ink composition has a viscosity from more than 2,000 cP to about 30,000 cP, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

2. The ink composition according to claim 1, wherein the phosphor material is present in an amount from about 5 wt % to about 70 wt %, based on the weight of the ink composition.

3. The ink composition according to claim 1, wherein the Mn⁴⁺ doped phosphor is selected from K₂[GeF₆]:Mn⁴⁺, K₂[SiF₆]:Mn⁴⁺, K₂[TiF₆]:Mn⁴⁺, K₂[SnF₆]:Mn⁴⁺, Cs₂[TiF₆]:Mn⁴⁺, Rb₂[TiF₆] Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆], K₃[YF₆]:Mn⁴⁺, K₃[LaF₆]:Mn⁴⁺, K₃[GdF₆]:Mn⁴⁺, K₃[NbF₇]:Mn⁴⁺, and K₃[TaF₇]:Mn⁴⁺.

4. (canceled)

5. The ink composition according to claim 1, wherein the Mn⁴⁺ doped phosphor of Formula I is coated with a surface coating comprising a metal fluoride.

6. (canceled)

7. The ink composition according to claim 1, wherein the phosphor material further comprises at least one of a rare earth containing a Garnet phosphor doped with cerium, β-SiAlON, or a quantum dot.

8. The ink composition according to claim 1, wherein the ink composition further comprises a binder material and a solvent.

9. The ink composition according to claim 8, wherein the binder material is one or more of an epoxy, acrylate, methacrylate, vinyl ester and siloxane.

10. The ink composition according to claim 1 further comprising a scattering aid.

11. The ink composition according to claim 10, wherein the scattering aid is ZrO₂ or TiO₂ nanoparticles.

12. The ink composition according to claim 1, wherein the ink composition further comprises one or more luminescent materials.

13-43. (canceled)

44. A color filter part comprising a well, a first ink phosphor composition and a second ink phosphor composition, the first ink composition comprising a high refractive index and the second ink phosphor composition comprising a low refractive index, wherein the second ink phosphor composition is located proximate to a surface through which excitation light enters,
the first ink phosphor composition and the second ink phosphor composition including a phosphor material including a Mn⁴⁺ doped phosphor of formula 1 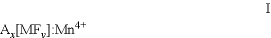
and at least one binder material or solvent, wherein the Mn⁴⁺ doped phosphor has a D50 particle size from about 0.5 microns to about 15 microns, and wherein the ink compositions have a viscosity from about 10,000 cP to about 30,000 cP, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

45. The color filter part according to claim 44, wherein the refraction index of the first ink composition is greater than about 1.5 and the refractive index of the second ink is about 0.1 to about 1.5.

46. The color filter part according to claim 45, wherein a depth of the well is about 6 μm to about 20 μm.

47. The color filter part according to claim 45, wherein at least one wall of the well is coated with a reflective material.

48. The color filter part according to claim 45, wherein at least a portion of the surface through which excitation light enters is coated with at least one film, the at least one film configured to change optical properties or improve reliability of the color filter part.

49-50. (canceled)

51. A light emitting array comprising a plurality of mini-LEDs or micro-LEDs, each mini-LED or micro-LED enclosed in a banked structure or a well structure, the banked structure or well structure configured to contain an ink composition deposited within the bank structure or the well structure,
the ink composition including a phosphor material including a Mn⁴⁺ doped phosphor of formula 1 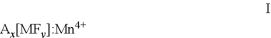
and at least one binder material or solvent, wherein the Mn⁴⁺ doped phosphor has a D50 particle size from about 0.5 microns to about 15 microns, and wherein the ink composition has a viscosity from about 10,000 cP to about 30,000 cP, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

52. A transparent display comprising a mini-LED array or a micro-LED array coated with a phosphor ink composition, wherein the transparent display has a transparency of at least 50%, the phosphor ink composition comprising a Mn⁴⁺ doped phosphor of formula 1, 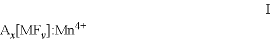
wherein the Mn⁴⁺ doped phosphor has a D50 particle size from about 0.5 microns to about 15 microns, and wherein the phosphor ink composition has an aspect ratio of at least 0.1, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

53. The transparent display of claim 52, wherein each mini-LED of the mini-LED array or each micro-LED of the micro-LED array is enclosed in a banked structure or a well structure.

54. (canceled)

55. An automotive display comprising the transparent display of claim 52.

56-77. (canceled)

78. The ink composition according to claim 12, wherein the one or more luminescent materials comprise at least one of [Y,Gd,Lu,Tb]₃[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, [Ba,Sr,Ca]₂Si₂O₄:Eu²⁺, or quantum dot material.
